(19) United States
(12) Patent Application Publication
(10) Pub. No.: US 2024/0347367 A1
(43) Pub. Date: Oct. 17, 2024

(54) INTEGRATED-CIRCUIT MODULE COLLECTION AND DEPOSITION

(71) Applicants: X-Celeprint Limited, Dublin (IE); LEONHARD KURZ Stiftung & Co. KG, Fürth (DE)

(72) Inventors: Ronald S. Cok, Rochester, NY (US); António José Marques Trindade, Cork (IE); MIchael Scharfenberg, Nürnberg (DE); Christian Schulz, Fürth (DE); Gabriele Roithmeier, Nürnberg (DE)

(21) Appl. No.: 18/294,754

(22) PCT Filed: Aug. 9, 2021
(86) PCT No.: PCT/EP21/72172

§ 371 Date: Feb. 2, 2024

(51) Int. Cl. H01L 21/683; H01L 23/00

(52) U.S. Cl. CPC H01L 21/6835; H01L 24/27; H01L 24/83; H01L 24/98; H01L 2224/27515; H01L 2224/27848; H01L 2224/8312; H01L 2224/98; H01L 2924/15156

(57) ABSTRACT

A module collection and deposition system comprises a container, a module source wafer comprising modules released from the module source wafer, a module collection device operable to remove the modules from the module source wafer and dispose the modules as a disordered and dry collection into the container, and a module deposition device for removing the modules from the container and randomly disposing the modules on a receiving surface. Each module comprises an electronically active unpackaged component.

### TECHNICAL FIELD

The present disclosure relates generally to methods, systems, and structures for disposing micro-structures on a substrate, in particular disposing micro-assembled integrated-circuit micro-devices formed on a wafer using photolithography onto a flexible substrate.

### BACKGROUND

Integrated circuits are widely used for electronic devices. In some applications, microscopic integrated circuits (micro-devices) are disposed on flexible substrates for consumer use and are subject to rough physical treatment. For high-volume applications, the micro-devices must be made and assembled on the flexible substrates at low cost. Micro-transfer printing structures and methods, for example as taught in U.S.

U.S. Pat. Nos. 10,150,325 and 10,675,905, disclose photolithographically constructed microscopic devices that can be assembled on flexible substrates, such as banknotes.

U.S. Pat. Nos. 5,545,291; 6,291,896 describe a method for fabricating self-assembling micro-structures fabricated by micro-machining individual components onto a substrate through fluid transport. Shaped micro-structure blocks are removed from a silicon wafer and transferred into a fluid to create a slurry. The slurry is then poured evenly over the top surface of a substrate having recessed regions shaped to complement the shaped micro-structure blocks. The micro-structures then tumble into and self-align with the recessed regions in the substrate. However, this method is difficult to employ with flexible substrates comprising a material that is incompatible with a slurry.

There remains a need for structures and methods that can be used to dispose micro-devices onto substrates at a very low cost and at very high volumes.

### SUMMARY

In certain embodiments of the present disclosure, a method of collecting and disposing modules comprises providing a module source wafer comprising modules, removing the modules from the module source wafer, disposing the modules as a disordered and dry collection into a container, removing the modules from the container, and disposing the modules on a receiving surface. Each module can comprise one or more electronically active unpackaged components.

In some embodiments, the module source wafer further comprises a sacrificial layer comprising laterally spaced-apart sacrificial portions, wherein each of the modules is disposed entirely over one of the sacrificial portions and the method comprises dry or wet etching the sacrificial portions to release the modules from the module source wafer.

According to some embodiments, after releasing the modules from the module source wafer, each of the modules is physically attached to the module source wafer by a tether.

According to some embodiments, after releasing the modules from the module source wafer, the modules are physically detached from the module source wafer.

According to some embodiments, removing the modules from the module source wafer comprises disposing the module source wafer with the modules near the container and etching the module source wafer with a dry etch so that the modules fall toward the bottom of the container.

According to some embodiments, removing the modules from the module source wafer comprises vibrating the module source wafer or modules.

According to some embodiments, vibrating the module source wafer comprises mechanically or sonically vibrating the modules, particularly by mechanically or sonically vibrating the module source wafer.

According to some embodiments, removing the modules from the module source wafer comprises directing a stream of gas or liquid onto the module source wafer such that the modules are released from the module source wafer.

According to some embodiments, removing the modules comprises rinsing the module source wafer with a liquid, preferably by directing a stream of liquid onto the module source wafer, such that the modules are removed from the module source wafer and a slurry of modules and liquid is formed, filtering the slurry with a filter to separate the liquid from the modules, and disposing the modules in the container.

According to some embodiments, removing the modules from the module source wafer comprises thinning the module source wafer and dicing the modules.

According to some embodiments, removing the modules comprises contacting the modules with a stamp to adhere the modules to the stamp, removing the stamp and the modules from the module source wafer, detaching the modules from the stamp, and collecting the modules in the container, particularly wherein detaching the modules causes the modules to fall into the container.

In some embodiments of the present disclosure, detaching the modules from the stamp comprises any one or combination of (i) heating the stamp or the modules; (ii) exposing the stamp or modules to radiation, (iii) vibrating the stamp, (iv) exposing the stamp to vibration, (v) rinsing the stamp, (vi) directing a stream of liquid onto the modules, and (vii) directing a stream of gas onto the modules.

According to some embodiments, removing the modules from the module source wafer comprises turning over the module source wafer such that the modules fall toward the bottom of the container.

According to some embodiments, methods of the present disclosure comprise entraining the modules in a flow of gas or flow of liquid while removing the modules from the module source wafer.

According to some embodiments, the receiving surface is chosen from the group: a surface of a document, a surface of a banknote, a surface of a foil, and a surface of a ribbon. The receiving surface can be a substrate and the method can comprise incorporating the substrate into a document or banknote.

According to some embodiments, the substrate is a foil or a ribbon.

According to some embodiments, each of the modules comprises one or more anti-stiction spikes. The modules can each have a length and a width independently not greater than 2500 μm, preferably not greater than 1500 μm, more preferably not greater than 750 μm, more preferably not greater than 500 μm, or more preferably not greater than 250 μm. The modules can be light-emitting modules. Modules can have a thickness not greater than 100 microns, preferably not greater than 50 μm, more preferably not greater than 20 μm, more preferably not greater than 10 μm, more preferably not greater than 5 μm, or more preferably not greater than 2 μm.

According to some embodiments, the modules each have at least one of: a length and a width over the receiving surface that is no less than two, preferably no less than five, more preferably no less than ten, more preferably no less than twenty, more preferably no less than fifty, or more preferably no less than one hundred times the thickness of the modules.

According to some embodiments, each of the modules comprises a broken, particularly fractured, or separated tether.

According to embodiments of the present invention, disposing the modules on a receiving surface comprises randomly sprinkling the modules onto the receiving surface, disposing the modules in a vibrating sieve over the receiving surface, or randomly disposing the modules on an intermediate surface and pouring the modules from the intermediate surface onto the receiving surface.

Some embodiments of the present disclosure comprise moving the receiving surface in a direction at least partially orthogonal to the force of gravity while disposing the modules on the receiving surface.

Some embodiments of the present disclosure comprise coating a layer of adhesive on the receiving surface that adheres at least some of the modules to the receiving surface.

Some embodiments of the present disclosure comprise coating a patterned layer of adhesive that adheres only some of the modules to the receiving surface in the pattern. Some embodiments of the present disclosure comprise heating the adhesive to reduce the viscosity of the adhesive and orient the modules with respect to the receiving surface and then cooling the adhesive, curing the adhesive using electromagnetic radiation, or curing the adhesive using a thermal treatment.

Some embodiments of the present disclosure comprise removing one or more non-adhered modules from the receiving surface and adding them back to the collection.

Some embodiments of the present disclosure comprise vibrating the receiving surface, re-orienting the receiving surface, rinsing the receiving surface, or exposing the receiving surface to a stream of gas or liquid to remove the one or more non-adhered modules from the receiving surface.

Some embodiments of the present disclosure comprise entraining the modules in a flow of gas or flow of liquid while removing the one or more non-adhered modules from the receiving surface.

Some embodiments of the present disclosure comprise orienting the modules with respect to the receiving surface, preferably as or after the modules are disposed on the receiving surface, particularly by providing an electric field and/or a magnetic field and/or a pattern of surface energy on the receiving surface.

In some embodiments of the present disclosure, the receiving surface is reflective.

According to embodiments of the present disclosure, a method of collecting modules comprises providing a module source wafer comprising modules, removing the modules from the module source wafer, and disposing the modules as a disordered and dry collection into a container. Each of the modules can comprise one or more electronically active unpackaged components. These components can be individually or in combination selected from the group: small integrated circuits, micro-devices, chiplets, unpackaged dies released from a native source substrate, and micro-transfer printed components.

According to some embodiments, the module source wafer comprises a sacrificial layer comprising laterally spaced-apart sacrificial portions, wherein each of the modules is disposed entirely over one of the sacrificial portions and methods of the present disclosure comprise dry or wet etching the sacrificial portions to release the modules from the module source wafer.

According to some embodiments, after releasing the modules from the module source wafer, each of the modules is physically attached to the module source wafer by a tether.

According to some embodiments, after releasing the modules from the module source wafer, the modules are physically detached from the module source wafer.

According to some embodiments, removing the modules from the module source wafer comprises disposing the module source wafer with the modules near the container and etching the module source wafer with a dry etch so that the modules fall toward the bottom of the container.

According to some embodiments, removing the modules from the module source wafer comprises vibrating the module source wafer or modules.

According to some embodiments, vibrating the module source wafer comprises mechanically or sonically vibrating the modules, preferably by mechanically or sonically vibrating the module source wafer.

According to some embodiments, removing the modules from the module source wafer comprises directing a stream of gas or liquid onto the module source wafer such that the modules are released from the module source wafer.

According to some embodiments, removing the modules comprises rinsing the module source wafer with a liquid, preferably by directing a stream of liquid onto the module source wafer, such that the modules are removed from the module source wafer and a slurry of modules and liquid is formed, filtering the slurry with a filter to separate the liquid from the modules, and disposing the modules in the container.

According to some embodiments, removing the modules from the module source wafer comprises thinning the module source wafer and dicing the modules.

According to some embodiments, removing the modules comprises contacting the modules with a stamp to adhere the modules to the stamp, removing the stamp and the modules from the module source wafer, detaching the modules from the stamp, and collecting the modules in the container, particularly wherein detaching the modules causes the modules to fall into the container.

According to some embodiments, detaching the modules from the stamp comprises any one or combination of (i) heating the stamp or the modules; (ii) exposing the stamp or modules to radiation, (iii) vibrating the stamp, (iv) exposing the stamp to vibration, (v) rinsing the stamp, (vi) directing a stream of liquid onto the modules, and (vii) directing a stream of gas onto the modules.

According to some embodiments, removing the modules from the module source wafer comprises turning over the module source wafer such that the modules fall toward the bottom of the container. Some embodiments of the present disclosure comprise entraining the modules in a flow of gas or flow of liquid while removing the modules from the module source wafer.

According to embodiments of the present disclosure, each of the modules comprises one or more anti-stiction spikes. In some embodiments, the modules each have a length and a width independently not greater than 2500 μm, preferably not greater than 1500 μm, more preferably not greater than 750 μm, more preferably not greater than 500 μm, or more preferably not greater than 250 μm.

According to some embodiments, the modules each have at least one of a length and a width over the receiving surface that is no less than two, preferably no less than five, more preferably no less than ten, more preferably no less than twenty, more preferably no less than fifty, or more preferably no less than one hundred times the thickness of the modules. The modules can be light-emitting modules.

According to some embodiments, the modules comprise a broken, particularly fractured, or separated tether.

According to embodiments of the present disclosure, a method of disposing a collection of modules on a receiving surface comprises providing a disordered and dry collection of modules in a container, removing the modules from the container, and disposing the modules on the receiving surface. Each of the modules can comprise one or more electronically active unpackaged components. The receiving surface is chosen from the group: a surface of a document, a surface of a banknote, a surface of a foil, and a surface of a ribbon. The receiving surface can be a substrate and the method comprising incorporating the substrate into a document or banknote. The substrate can be a foil or a ribbon.

According to some embodiments, each of the modules comprises one or more anti-stiction spikes. The modules can each have a length and a width independently not greater than 2500 μm, preferably not greater than 1500 μm, more preferably not greater than 750 μm, more preferably not greater than 500 μm, or more preferably not greater than 250 μm. The modules can each have at least one of a length and a width over the receiving surface that is no less than two preferably no less than five, more preferably no less than ten, more preferably no less than twenty, more preferably no less than fifty, or more preferably no less than one hundred times the thickness of the modules.

One electronically active unpackaged component can have a width and/or a length and/or a height from 0.5 μm to 20 μm, preferably from 1 μm to 15 μm, or more preferably from 5 μm to 10 μm.

The modules can be light-emitting modules.

According to embodiments, each of the modules comprises a broken, particularly fractured, or separated tether.

According to embodiments of the present disclosure, removing the modules from the container and disposing the modules on a receiving surface can comprise randomly sprinkling the modules onto the receiving surface, disposing the modules in a vibrating sieve over the receiving surface, or randomly disposing the modules on an intermediate surface and pouring the modules from the intermediate surface onto the receiving surface.

Methods of the present disclosure can comprise moving the receiving surface in a direction at least partially orthogonal to the force of gravity while disposing the modules on the receiving surface, coating a layer of adhesive on the receiving surface that adheres at least some of the modules to the receiving surface, or coating a patterned layer of adhesive that adheres only some of the modules to the receiving surface in the pattern.

Some methods comprise heating the adhesive to reduce the viscosity of the adhesive and orient the at least some of the modules with respect to the receiving surface, and then cooling the adhesive, curing the adhesive using electromagnetic radiation, or curing the adhesive using a thermal treatment.

According to the present disclosure, some methods comprise removing one or more non-adhered modules from the receiving surface and adding them back to the collection. Some methods can comprise vibrating the receiving surface, re-orienting the receiving surface, rinsing the receiving surface, or exposing the receiving surface to a stream of gas or liquid to remove the one or more non-adhered modules from the receiving surface.

Some methods can comprise entraining the modules in a flow of gas or flow of liquid while removing the one or more non-adhered modules from the receiving surface. Some methods can comprise providing an electric field and/or magnetic field and/or a pattern of surface energy on the receiving surface to orient the modules with respect to the receiving surface.

In some embodiments, the receiving surface is reflective.

According to embodiments of the present disclosure, a module collection and deposition system comprises a container, a module collection device operable to remove modules from a module source wafer and dispose the modules as a disordered and dry collection into the container, and a module deposition device for removing the modules from the container and randomly disposing the modules on a receiving surface.

In some embodiments, the collection device comprises a module removal device that is operable to remove the modules from the module source wafer by directing a stream of gas onto the module source wafer to remove the modules from the module source wafer and dispose the removed modules in the container.

In some embodiments, the collection device comprising a module removal device and a filter and the module removal device is operable to remove the modules from the module source wafer by rinsing the module source wafer and modules with a liquid, preferably by directing a stream of liquid onto the module source wafer and modules to remove the modules from the module source wafer, and form a slurry of modules and liquid, causing (i) the slurry to be filtered with the filter to separate the liquid from the modules and (ii) the modules to be disposed in the container after being filtered.

In some embodiments, the collection device is operable to remove the modules from the module source wafer by disposing the module source wafer in or over the container with a top side of the module source wafer on a side of the module source wafer opposite a bottom of the container and turning over the wafer so that the modules fall toward the bottom of the container.

In some embodiments, the collection device comprises a stamp and is operable to remove the modules from the module source wafer by contacting the modules with the stamp to adhere the modules to the stamp, removing the stamp and modules from the module source wafer, detaching the modules from the stamp, and disposing the detached modules in the container, particularly wherein detaching the modules causes the modules to fall into the container.

In some embodiments, the collection device is operable to (i) heat the stamp or the modules when on the stamp; (ii) expose the stamp or the modules when on the stamp to radiation, (iii) vibrate the stamp or expose the stamp to vibration, (iv) rinse the stamp, (v) direct a stream of liquid onto the modules when on the stamp, or (vi) direct a stream of gas onto the modules when on the stamp.

In some embodiments, the collection device comprises a module removal device comprising a vibrator that is disposed to vibrate the module source wafer to remove the modules from the module source wafer. In some embodiments, the collection device is operable to vibrate the module source wafer mechanically or sonically.

According to some embodiments, the collection device comprises a gas or liquid source that is operable to entrain the modules in a flow of gas or flow of liquid, respectively, while removing the modules from the module source wafer.

In some embodiments of the present disclosure, each of the modules comprises one or more anti-stiction spikes. In some embodiments, the modules have a length and a width independently not greater than 2500 μm, preferably not greater than 1500 μm, more preferably not greater than 750 μm, more preferably not greater than 500 μm, or more preferably not greater than 250 μm). The modules can have a length or width, or both, over the receiving surface that is no less than two preferably no less than five, more preferably no less than ten, more preferably no less than twenty, more preferably no less than fifty, or more preferably no less than one hundred times a thickness of the modules when disposed on the receiving surface. In some embodiments, the modules are light-emitting modules. Each of the modules can comprise a fractured or separated tether.

According to some embodiments of the present disclosure, the deposition device comprises a sprinkler for randomly disposing the modules on the receiving surface, a vibrating sieve for randomly disposing the modules on the receiving surface, or the deposition device is operable to randomly dispose the modules on an intermediate substrate and pour the modules from the intermediate substrate onto the receiving substrate. The deposition device can be operable to move the receiving surface in a direction at least partially orthogonal to the force of gravity while disposing the modules on the receiving surface. The deposition device can comprise an adhesive source, preferably an inkjet printer or slot coater, that is operable to coat a layer of adhesive on the receiving surface. The adhesive source can be operable to pattern the layer of adhesive on the receiving surface.

According to some embodiments of the present disclosure, the deposition device comprises one or more rollers operable to move the receiving surface relative to the container to deposit the modules over the receiving surface, preferably wherein the receiving surface is rolled onto and/or off of one(s) of the one or more rollers.

According to some embodiments of the present disclosure, a module collection and deposition system comprises a recycling container, wherein the deposition device is operable to remove non-adhered modules from the receiving surface, collect them in the recycling container, and add them back to the collection from the recycling container.

The recycling container can be disposed adjacent to one or more rollers such that non-adhered modules are removed, particularly such that modules that are not adhered to the preferably patterned, adhesive are removed and collected in the recycling container by falling into the recycling container.

The deposition device can be operable to vibrate the receiving surface, re-orient the receiving surface, rinse the receiving surface, or expose the receiving surface to a stream of gas or liquid to remove non-adhered modules from the receiving surface. The deposition device can comprise a gas or liquid source that is operable to entrain the modules in a flow of gas or flow of liquid, respectively, when removing the non-adhered modules from the receiving surface.

Embodiments of the present disclosure can comprise a heater for heating adhesive disposed on the receiving surface to reduce the viscosity of the adhesive and orient the modules with respect to the receiving surface when the modules are disposed on the adhesive.

According to some embodiments, the deposition device comprises a field source, particularly in the form of plates, that is operable to apply an electric field and/or a magnetic field to orient the modules with respect to the receiving surface or the system comprises the receiving surface that comprises a surface energy pattern to orient the modules with respect to the receiving surface.

According to some embodiments, the receiving surface can be reflective or the receiving surface can be a web. Embodiments of the present disclosure comprise a coater for coating the modules on the receiving surface. The receiving surface is chosen from the group: a surface of a document, a surface of a banknote, a surface of a foil, a surface of a ribbon, and a substrate incorporated into a document or banknote.

Module collection and deposition system of the present disclosure can comprise a module source wafer comprising modules, particularly modules attached to the module source wafer by tethers, wherein the modules are released from the module source wafer. Some embodiments comprise one or more rollers that are operable to move the receiving surface to dispose the modules over the receiving surface. Some embodiments comprise a recycling container disposed adjacent to the one or more rollers for collecting non-adhered modules.

According to embodiments of the present disclosure, a module collection system comprises a container, a module source wafer comprising modules released from the module source wafer, and a collection device operable to remove the modules from the module source wafer and dispose the modules as a disordered and dry collection into the container.

Each module can comprise an electronically active unpackaged component.

The collection device can comprise a module removal device that is operable to remove the modules from the module source wafer by directing a stream of gas or liquid onto the module source wafer to remove the modules from the module source wafer and dispose the removed modules in the container.

The collection device can comprise a module removal device and a filter and the module removal device can be operable to remove the modules from the module source wafer by rinsing the module source wafer and modules with a liquid, preferably by directing a stream of liquid onto the module source wafer and modules to remove the modules from the module source wafer, and form a slurry of modules and liquid, causing (i) the slurry to be filtered with the filter to separate the liquid from the modules and (ii) the modules to be disposed in the container after being filtered. The modules can be dried.

The collection device can be operable to remove the modules from the module source wafer by disposing the module source wafer in or over the container with a top side of the module source wafer on a side of the module source wafer opposite a bottom of the container and turning over the wafer so that the modules fall toward the bottom of the container.

The collection device can comprise a stamp operable to remove the modules from the module source wafer by contacting the modules with the stamp to adhere the modules to the stamp, removing the stamp and modules from the module source wafer, detaching the modules from the stamp, and disposing the detached modules in the container, particularly wherein detaching the modules causes the modules to fall into the container.

In some embodiments, the collection device can be operable to (i) heat the stamp or the modules when on the stamp, (ii) expose the stamp or modules when on the stamp to radiation, (iii) vibrate the stamp or expose the stamp to vibration, (iv) rinse the stamp, (v) direct a stream of liquid onto the modules when on the stamp, or (vi) direct a stream of gas onto the modules when on the stamp.

The collection device can comprise a module removal device comprising a vibrator that is operable to vibrate the module source wafer to remove the modules from the module source wafer. The collection device can be operable to vibrate the module source wafer mechanically or sonically. The collection device can comprise a gas or liquid source that is operable to entrain the modules in a flow of gas or flow of liquid, respectively, while removing the modules from the module source wafer.

According to embodiments of the present disclosure, each of the modules comprises one or more anti-stiction spikes, the modules have a length and a width not greater than 2500 μm, preferably not greater than 1500 μm, more preferably not greater than 750 μm, more preferably not greater than 500 μm, or more preferably not greater than 250 μm. The modules have a length or width, or both, that is no less than two, preferably no less than five, more preferably no less than ten, more preferably no less than twenty, more preferably no less than fifty, or more preferably no less than one hundred times a thickness of the modules, the modules are light-emitting modules, or each of the modules comprises a broken, particularly fractured, or separated tether.

According to embodiments of the present disclosure, a module deposition system comprises a container containing a disordered and dry collection of modules, and a deposition device for removing the modules from the container and randomly disposing the modules on a receiving surface. Each of the modules can comprise an electronically active unpackaged component.

The deposition device can comprise a sprinkler for randomly disposing the modules on the receiving surface, a vibrating sieve for randomly disposing the modules on the receiving surface, or the deposition device is operable to randomly dispose the modules on an intermediate substrate and pour the modules from the intermediate substrate onto the receiving substrate.

The deposition device can be operable to move the receiving surface in a direction at least partially orthogonal to the force of gravity while disposing the modules on the receiving surface. The deposition device can comprise one or more rollers that are operable to move the receiving surface. The deposition device can comprise an adhesive source, preferably an inkjet printer or slot coater, that is operable to coat a layer of adhesive on the receiving surface. The adhesive source can be operable to pattern the layer of adhesive on the receiving surface.

According to embodiments of the present disclosure, the module deposition system can comprise a recycling container, wherein the deposition device is operable to remove non-adhered modules from the receiving surface, collect them in the recycling container, and add them back to the collection from the recycling container. The recycling container can be disposed adjacent to one or more rollers such that non-adhered modules are removed, particularly such that modules that are not adhered to the preferably patterned, adhesive are removed and collected in the recycling container by falling into the recycling container. The deposition device can be operable to vibrate the receiving surface, re-orient the receiving surface, rinse the receiving surface, or expose the receiving surface to a stream of gas or liquid to remove non-adhered modules from the receiving surface. The deposition device can comprise a gas or liquid source that is operable to entrain the modules in a flow of gas or flow of liquid, respectively, when removing the non-adhered modules from the receiving surface.

According to embodiments of the present disclosure, a module deposition device can comprise a heater for heating adhesive disposed on the receiving surface to reduce the viscosity of the adhesive and orient the modules with respect to the receiving surface when the modules are disposed on the adhesive. The deposition device can comprise a field source, particularly in the form of plates, that is operable to apply an electric field and/or a magnetic field to orient the modules with respect to the receiving surface or the system comprises the receiving surface that comprises a surface energy pattern to orient the modules with respect to the receiving surface.

According to embodiments of the present disclosure, the receiving surface is reflective or the receiving surface is a web. The receiving surface is chosen from the group: a surface of a document, a surface of a banknote, a surface of a foil, a surface of a ribbon, and a substrate incorporated into a document or banknote.

Embodiments of the present disclosure can comprise a coater for coating the modules on the receiving surface.

Certain embodiments of the present disclosure provide micro-devices and methods of disposing the micro-devices on a substrate at very high volumes and at very low cost.

### BRIEF DESCRIPTION OF THE DRAWINGS

The foregoing and other objects, aspects, features, and advantages of the present disclosure will become more apparent and better understood by referring to the following description taken in conjunction with the accompanying drawings, in which:

FIG. 1 is a flow diagram according to illustrative embodiments of the present disclosure;

FIGS. 2A and 2B are schematic cross sections of a module disposed on a module source wafer according to illustrative embodiments of the present disclosure;

FIG. 3A is a schematic cross section of tethered modules disposed over a sacrificial portion of a module source wafer according to illustrative embodiments of the present disclosure;

FIG. 3B is a schematic cross section of untethered modules disposed over a sacrificial portion of a module source wafer according to illustrative embodiments of the present disclosure;

FIG. 4A is a schematic cross section of tethered modules disposed over and released from a sacrificial portion of a module source wafer according to illustrative embodiments of the present disclosure;

FIG. 4B is a schematic cross section of untethered modules disposed over and released from a sacrificial portion of a module source wafer according to illustrative embodiments of the present disclosure;

FIGS. 4C-4F are successive schematic cross sections of untethered modules disposed over and released from sacrificial portions of a module source wafer according to illustrative embodiments of the present disclosure;

FIG. 5 is a schematic cross section of a stamp adhered to released and untethered modules disposed over a module source wafer according to illustrative embodiments of the present disclosure;

FIG. 6 is a schematic cross section of modules adhered to a stamp and removed from the stamp with a stream according to illustrative embodiments of the present disclosure;

FIG. 7 is a schematic cross section of modules falling from a module source wafer according to illustrative embodiments of the present disclosure;

FIG. 8 is a schematic cross section of a dry disordered collection of modules with anti-stiction structures in a container according to illustrative embodiments of the present disclosure;

FIG. 9 is a module collection system according to illustrative embodiments of the present disclosure;

FIG. 10 is a module deposition system according to illustrative embodiments of the present disclosure;

FIG. 11 is a module collection and deposition system according to illustrative embodiments of the present disclosure;

FIG. 12 is a micrograph of a component with anti-stiction spikes according to illustrative embodiments of the present disclosure;

FIG. 13 is an illustration of components that are not all oriented parallel to the substrate according to illustrative embodiments of the present disclosure;

FIG. 14 is an illustration of components physically pressed down according to illustrative embodiments of the present disclosure;

FIG. 15 is an illustration of components with wicking adhesive providing surface energy according to illustrative embodiments of the present disclosure; and

FIG. 16 is an illustration of components that are oriented parallel to the substrate according to illustrative embodiments of the present disclosure.

The features and advantages of the present disclosure will become more apparent from the detailed description set forth below when taken in conjunction with the drawings, in which like reference characters identify corresponding elements throughout. In the drawings, like reference numbers generally indicate identical, functionally similar, or structurally similar elements. The figures are not drawn to scale since the variation in size of various elements in the Figures is too great to permit depiction to scale.

### DETAILED DESCRIPTION OF CERTAIN EMBODIMENTS

The disclosed technology, inter alia, relates generally to systems and methods for the collection of modules comprising one or more electronically active unpackaged components from a module source wafer and deposition of the modules on a receiving surface of a receiving substrate separate that is distinct, and independent of the modules. The components can be integrated circuits comprising a component substrate or an assembly of integrated circuits forming a module comprising a module substrate on which the assembly is disposed and interconnected. The systems and methods are well adapted to efficiently disposing large numbers of modules (e.g., many millions) onto the receiving substrate at low cost without chemically or mechanically stressing the modules.

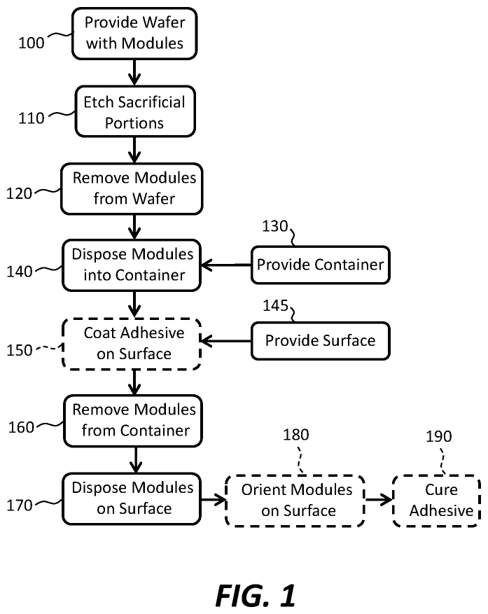

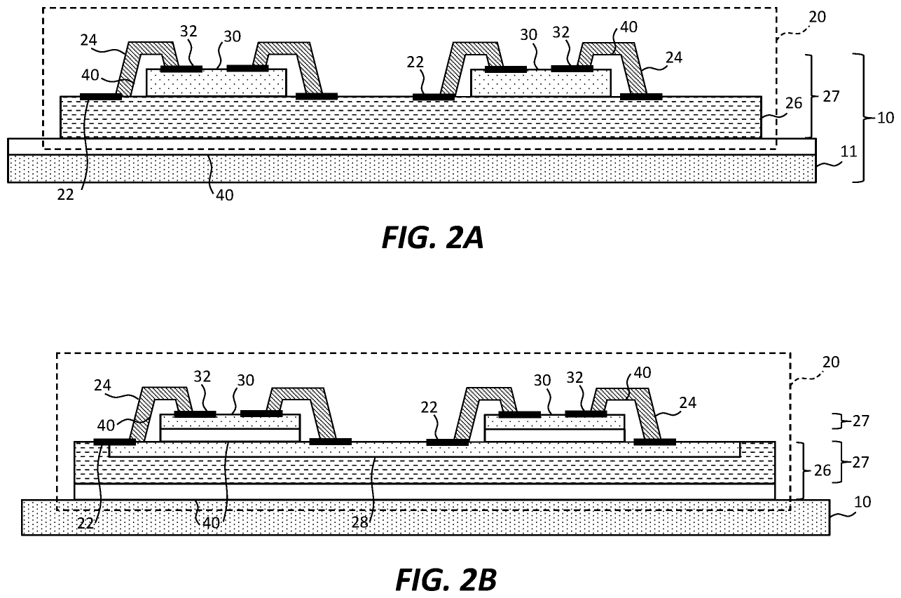

As illustrated in the embodiments of flow diagram FIG. 1 and as shown in FIGS. 2A and 2B, a method of collecting and disposing modules comprises providing a module source wafer 10 having modules 20 in step 100. Modules 20 comprise one or more electronically active unpackaged components 30, particular (e.g., integrated circuits or micro-devices 30 comprising electronic or opto-electronic circuits). In some embodiments, modules 20 can be or consist of a single unpackaged component 30 or, in some embodiments and as shown in FIGS. 2A, 2B, modules 20 comprise one or more unpackaged components 30 disposed and assembled on module substrate 26. Modules 20 and components 30 can be bare die. An unpackaged component 30 or module 20 can be a component 30 or module 20 that does not comprise a package into which a circuit, component 30, or module 20 is disposed and to which the circuit, component 30, or module 20 is electrically connected to package pins or package electrical contacts, e.g., through wire bonds. Generally, a package has a structure or package substrate separate and independent from a component substrate (e.g., a native component substrate on or in which a circuit is formed or disposed) and to which the component substrate is adhered or otherwise affixed or has a structure or package substrate separate and independent from a module substrate 26 on which components 30 are assembled and interconnected. A component 30 that is not disposed in a package and electrically connected to package connections is an unpackaged component 30 and a module 20 that is not disposed in a package and electrically connected to package connections is an unpackaged module 20, for example comprising a module substrate 26.

Individual components 30 can have a component substrate that is a module substrate 26. For example, as shown in FIG. 2A an integrated circuit can be formed in an epitaxial layer 27 on a process side of a semiconductor module source wafer 10, for example a semiconductor on insulator module source wafer 10 with a bulk layer 11, an insulating layer (dielectric layer 40) and an epitaxial layer 27 (including module substrate 26). In some such embodiments, portions of semiconductor module source wafer 10 serve as a component or module substrate 26 (e.g., a portion of epitaxial layer 27 with or without a dielectric layer 40) and one or more components 30 (e.g., all or only some) are native to module substrate 26. In some embodiments and as shown in FIG. 2B, modules 20 are assemblies of integrated circuits (e.g., components 30) and any other passive or active components 30 disposed on module substrate 26 and can be connected (e.g., electronically, optically, or opto-electronically) to an electronic or opto-electronic circuit formed in or on and native to module substrate 26. Module substrates 26 can be semiconductors or dielectrics, for example silicon (e.g., crystalline silicon), silicon dioxide, or silicon nitride. Module substrates 26 can have multiple layers.

Module 20 can comprise one or more of an inorganic light emitter, such as a light-emitting diode (e.g., a micro-light-emitting diode) or laser, a charge-storage device such as a capacitor, a power generator such as a piezo-electric structure, a power converter, an inductor, or an integrated circuit such as a controller, and can comprise silicon devices, electrical conductors such as metal or transparent conductive oxide wires, and compound semiconductor devices. Modules 20 can be constructed using photolithographic methods and materials and micro-transfer printing methods, tools, and devices. Module source wafer 10 can be a silicon-on-insulator (SOI) wafer or substrate and dielectric 40 underlying component 30 can be, for example, a patterned portion of the insulator (e.g., buried oxide or nitride layer) of SOI embodiments of module source wafer 10 and can comprise module substrate 26. In some such embodiments, component 30 or module 20 can comprise a patterned portion of an epitaxial layer of an SOI wafer, e.g., module circuit 28, as well as components 30.

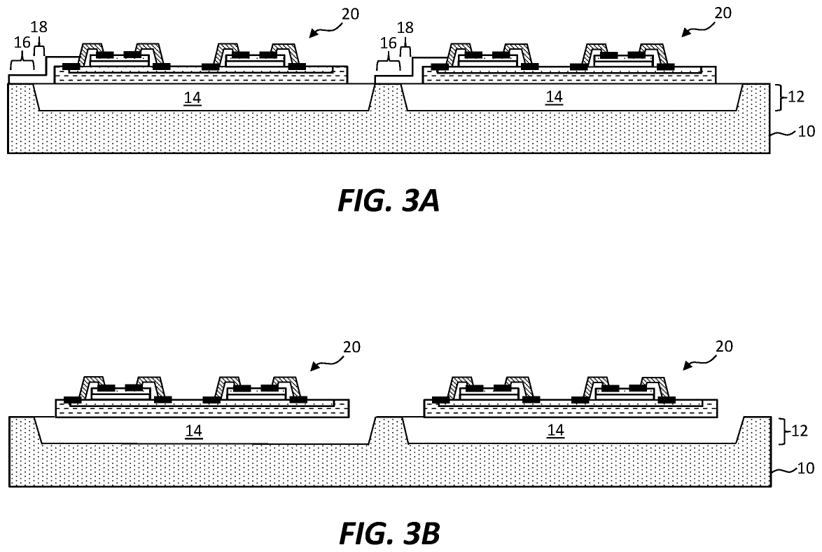

Each component 30 can have one or more component electrical contacts 32 electrically connected by module electrodes 24 to module electrical contacts 22 on module substrate 26 and insulated by patterned dielectric 40. Module electrical contacts 22 can be electrically connected or electrically connected to module circuit 28, if present. As illustrated in FIG. 2B, module substrate 26 can be or comprise a dielectric layer (e.g., dielectric layer 40), an epitaxial layer (e.g., epitaxial layer 27), or a combination thereof, onto which individual components 30 are disposed, for example by micro-transfer printing, or in which module circuits 28 are formed and electrically connected, for example by wires patterned using photolithographic methods and materials. As shown in FIG. 3A, modules 20 can comprise broken (e.g., fractured) or separated tethers 18 or, as shown in FIG. 3B, modules 20 do not comprise broken (e.g., fractured) or separated tethers 18.

In some embodiments, component(s) 30 are non-native to module substrate 26 and can be micro-transfer printed to module substrate 26. The electronic or opto-electronic circuits can comprise only electrically connected component(s) 30 disposed on module substrate 26 (for example where module substrate 26 is a dielectric substrate or is electrically insulating) or can comprise electrically connected components 30 disposed on module substrate 26 in combination with a module circuit 28 formed in module substrate 26 (e.g., in an epitaxial layer of module substrate 26 where module 20 comprises a semiconductor, such as silicon, for example crystalline silicon so that module circuit 28 is native to module substrate 26). Modules 20 comprising component(s) 30, electrical connections, and module substrate 26 can be constructed using photolithographic methods and materials and assembled using micro-transfer printing and can therefore comprise broken (e.g., fractured) or separated tethers 18. Component(s) 30 can be native to module 20 (e.g., photolithographically patterned on module substrate 26) or non-native to module 20 (e.g., micro-transfer printed onto module substrate 26). Components 30 can comprise digital, analog, or mixed-signal CMOS integrated circuits, capacitors, resistors, light-emitting diodes, or power-generation devices such as piezo-electric devices. In some embodiments, modules 20 can convert mechanical motion into light, for example by including one or more piezoelectric power generators and one or more light emitters (and optionally a control circuit).

As shown in the embodiments of FIG. 3A, modules 20 can be disposed entirely over a sacrificial portion 14 of a sacrificial layer 12 (e.g., an oxide layer) of module source wafer 10. Each module 20 can be physically connected by a tether 18 to an anchor 16 that laterally separates sacrificial portions 14 and modules 20. In some embodiments, not shown, modules 20 are physically connected by tether 18 to anchors 16 beneath modules 20. In some embodiments, and as shown in FIG. 3B, modules 20 are disposed entirely over a sacrificial portion 14 of a sacrificial layer 12 (e.g., an anisotropically etchable semiconductor layer) of module source wafer 10 but are not, in contrast to the embodiments of FIG. 3A, connected by a tether 18 to anchors 16.

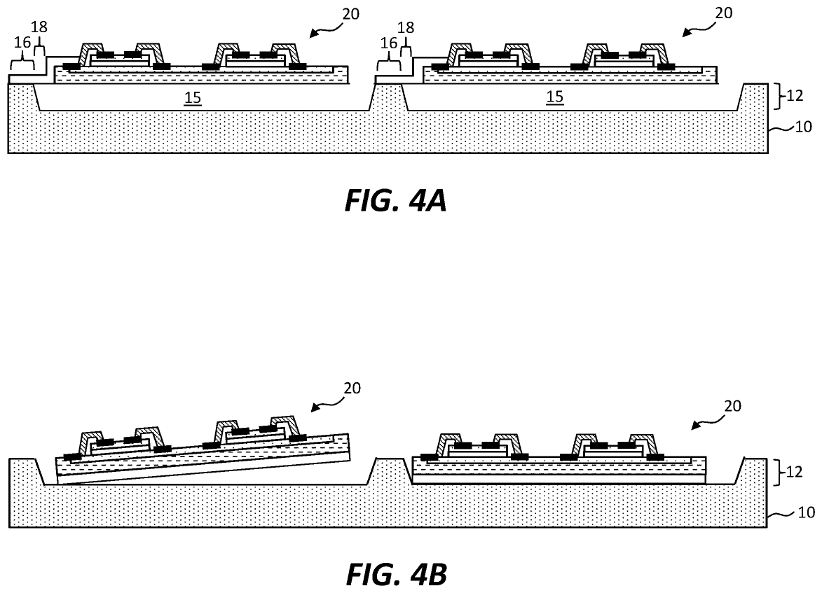

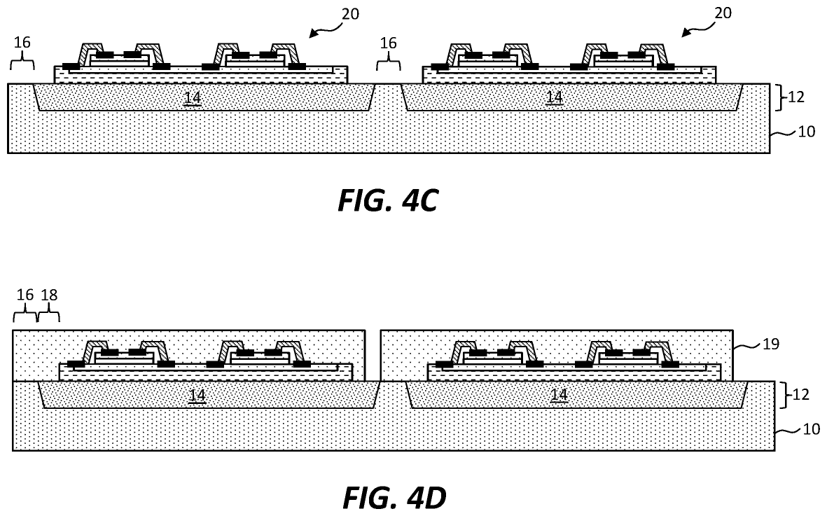

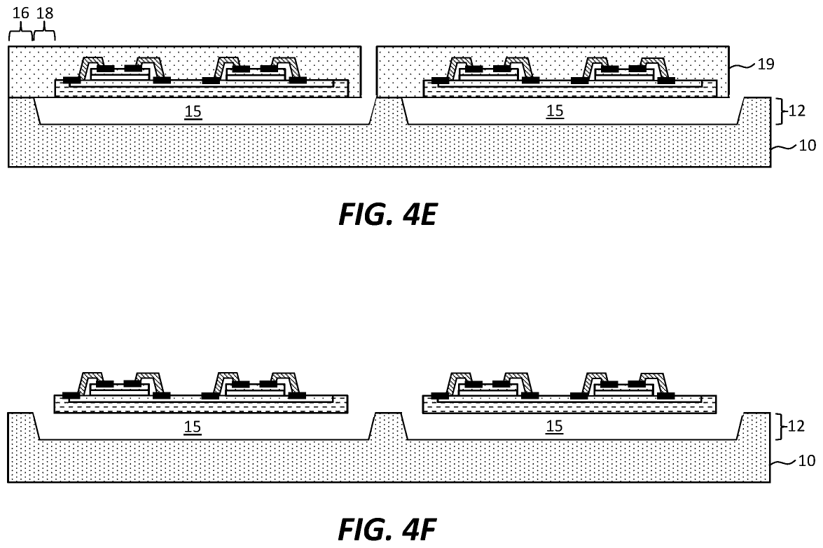

In step 110 of FIG. 1 and as illustrated in FIGS. 4A and 4B corresponding to FIGS. 3A and 3B, respectively, sacrificial portions 14 are etched, e.g., by dry etching and/or wet etching, to release modules 20 from module source wafer 10 to convert sacrificial portion 14 to a gap 15.

As illustrated in FIG. 4A and with reference to FIG. 3A, in some embodiments after etching sacrificial portions 14 modules 20 are physically connected to module source wafer 10 only by tethers 18 to anchors 16. Tethers 18 can hold modules 20 in spatial registration with module source wafer 10 and can aid in removal of modules 20 from module source wafer 10.

As illustrated in FIG. 4B and with reference to FIG. 3B, in some embodiments after etching sacrificial portions 14 modules 20 are physically detached from module source wafer 10 and can, for example, fall into gap 15 (etched sacrificial portion 14) in a disoriented or spatially unregistered state. Module source wafer 10 can be a crystalline silicon wafer and sacrificial portions 14 can be portions of sacrificial layer 12 and module source wafer 10 that etch anisotropically (e.g., a semiconductor material) or comprises a material (e.g., an oxide or nitride material) that is differentially etchable from a material of module source wafer 10 (e.g., a semiconductor material). Modules 20 can be encapsulated with a dielectric 40 (e.g., silicon dioxide or silicon nitride) encapsulating layer and module substrate 26 can be a dielectric 40 (e.g., silicon dioxide or silicon nitride) that serves as an etch stop, protecting modules 20 from sacrificial portion 14 etch step 110.

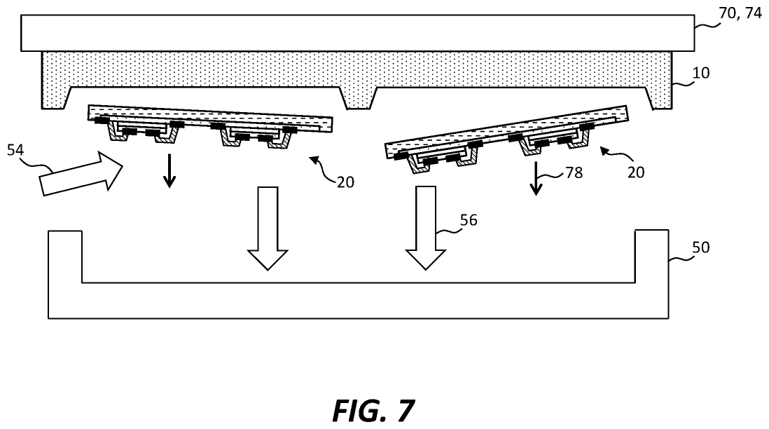

In some embodiments and as shown in FIGS. 4C-4F, modules 20 on sacrificial portions 14 of module source wafer 10 (as shown in FIG. 4C and similar to FIG. 3B) are first coated with a protective temporary tether 19 layer (e.g., a patterned coating of SiNx that extends over at least a portion of modules 20 and anchors 16 leaving an opening to etch sacrificial portion 14), as shown in FIG. 4D. The protective temporary tether 19 layer can be very thin, for example 0.5-2 μm thick, and easily removed. Sacrificial portions 14 are then etched to form gaps 15 between modules 20 and module source wafer 10 but leaving modules 20 still affixed to module source wafer 10 by protective temporary tethers 19, as shown in FIG. 4E. The protective temporary tethers 19 provide protection to components 30 from the sacrificial portion 14 etchant and, after sacrificial portion 14 etching is complete, are selectively removed (e.g., by etching such as a relatively gentle dry etching) completely dissociating modules 20 and module source wafer 10 as shown in FIG. 4F. Modules 20 are then free to fall into gap 15 (as shown in FIG. 4B) or away from module source wafer 10 into container 50, as shown in FIG. 7, discussed below. Protective temporary tether 19 can also be used to supplement tether 18 when tethers 18 are used. The use of protective temporary tether 19 can help to protect modules 20 during sacrificial portion 14 etching. Typically a wet etch that can mechanically stress modules 20 or undesirably chemically attack modules 20, for example a top side of modules 20.

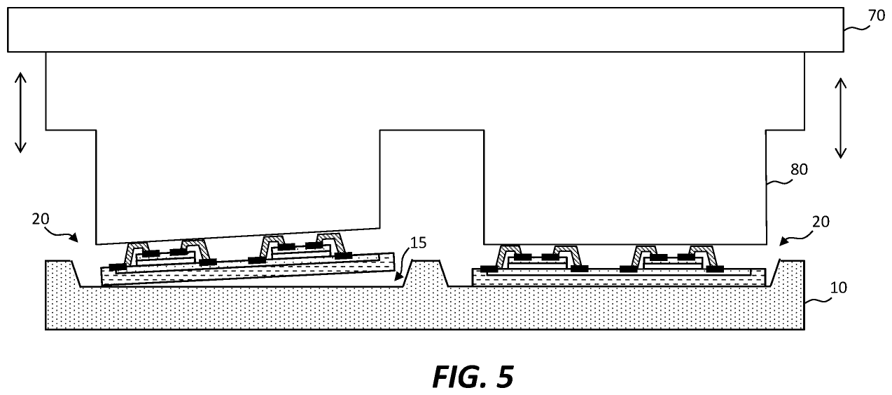

In step 120 of FIG. 1, modules 20 are removed (e.g., physically detached) from module source wafer 10. In some embodiments, step 120 removal is done using micro-transfer printing techniques and devices. In some embodiments (e.g., the embodiments of FIGS. 4A and 4B), modules 20 can be adhered to a stamp 80, e.g., a viscoelastic stamp 80 as shown in FIG. 5, and removed from module source wafer 10 by a motion platform 70, for example comprising a high-resolution electromechanical stage with optical alignment capability. FIG. 5 illustrates untethered modules 20; in some other embodiments, tethered modules 20 (e.g., as shown in FIGS. 3A, 4A) are adhered to stamp 80 and tethers 18 are broken (e.g., fractured). In step 130, a container 50 is provided into which modules 20 on stamp 80 can be disposed.

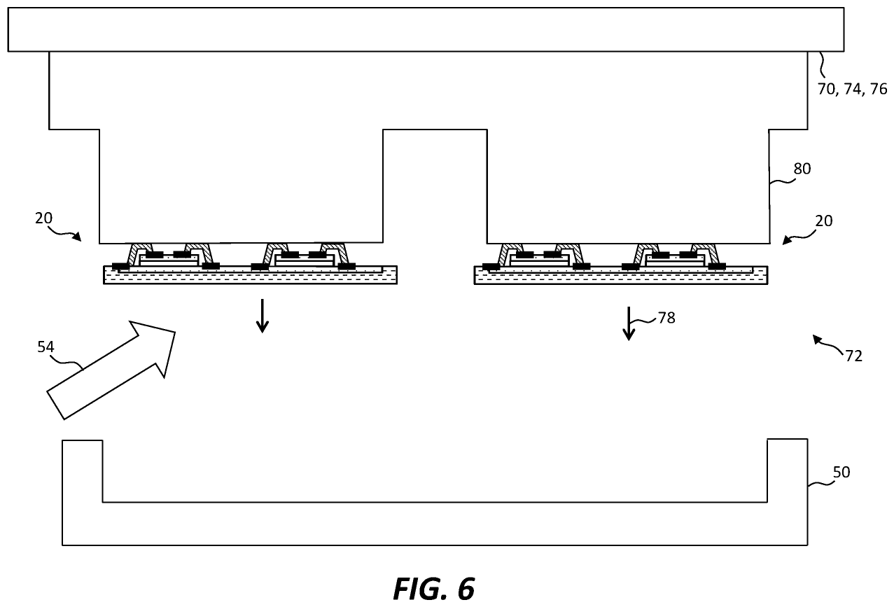

As shown in FIG. 6, detaching modules 20 from stamp 80 and disposing modules 20 into container 50 in step 140 with a module removal device 72 can comprise any one or combination of heating stamp 80 or modules 20 (e.g., with a heater 76) or exposing stamp 80 or modules 20 to radiation to differentially heat stamp 80 and modules 20 so that differences in coefficient of thermal expansion (CTE) cause stamp 80 to expand differently from modules 20 thereby breaking the adhesion between stamp 80 and modules 20 so modules 20 fall away from stamp 80 in a direction of gravity 78 into container 50 as a dry and disordered collection of modules 20. According to some embodiments of the present disclosure, modules 20 are removed from stamp 80 and disposed as a dry and disordered collection of modules 20 in a container 50 by mechanically vibrating stamp 80 or modules 20 with a vibrator 74 to shake (e.g., dislodge or detach) modules 20 into container 50 or exposing stamp 80 or modules 20 to vibration (e.g., ultrasonic vibration transmitted through stamp 80 or ambient air) from a vibrator 74. Vibrator 74 can be a piezoelectric vibrator. In some embodiments, methods of the present disclosure comprise any one or more of rinsing stamp 80, for example with a de-ionized liquid such as water, to wash modules 20 from stamp 80, directing a stream 54, e.g., a jet, of liquid (e.g., a de-ionized liquid such as water) onto modules 20 or directing a stream of gas, e.g., with a stream 54 of dry air or nitrogen, onto modules 20.

Any of these methods can be performed by module removal device 72 in or above container 50 so that modules 20 can fall in a direction of gravity 78 into container 50. In embodiments in which a liquid is used to physically detach modules 20 from stamp 80, a slurry comprising the liquid and modules 20 can be formed and the slurry filtered with a filter (e.g., a filter paper, or an open weave metal or plastic mesh) to separate modules 20 from the liquid. Modules 20 can be dried (e.g., with dry air or nitrogen) if necessary, and modules 20 disposed in container 50.

In some embodiments, module source wafer 10 is disposed so that modules 20 are on a side of module source wafer 10 adjacent container 50 in a direction of gravity 78 so that modules 20 can fall from module source wafer 10 into container 50, e.g., so that module source wafer 10 is upside down with respect to the direction of gravity 78. In some such embodiments, removing modules 20 from module source wafer 10 comprises disposing module source wafer 10 in or over container 50 with a top side of module source wafer 10 on a side of module source wafer 10 opposite a bottom of container 50 and turning over module source wafer 10 with or without vibration so that modules 20 fall toward the bottom of container 50.

In addition, or alternatively and as illustrated in FIG. 7 and with respect to FIGS. 3B, 4B, and 4F, in some embodiments, a stream 54 of gas, e.g., compressed air or nitrogen, is directed toward and onto modules 20 to separate modules 20 from stamp 80.

In some embodiments, sacrificial portions 14 are dry etched with modules 20 disposed on a side of module source wafer 10 adjacent container 50 so that, when modules 20 are detached from module source wafer 10 by the etchant, modules 20 fall into container 50 in a direction of gravity 78 after etching is complete.

In some embodiments of the present disclosure, removing modules 20 from module source wafer 10 comprises thinning module source wafer 10 and dicing modules 20, for example by laser or diamond cutting module source wafer 10 to singulate modules 20 from module source wafer 10 and disposing modules 20 into container 50.

According to some embodiments, methods of the present disclosure comprise entraining modules 20 in a flow 56 of gas or flow 56 of liquid while removing modules 20 from module source wafer 10. The flow 56 can assist with module 20 collection and deposition into container 50. Container 50 can comprise a mesh having holes (not shown in the figures) smaller than modules 20 to assist in flowing the gas or liquid and, if a liquid is used, to remove the liquid and provide a dry and disordered collection of modules 20 in container 50.

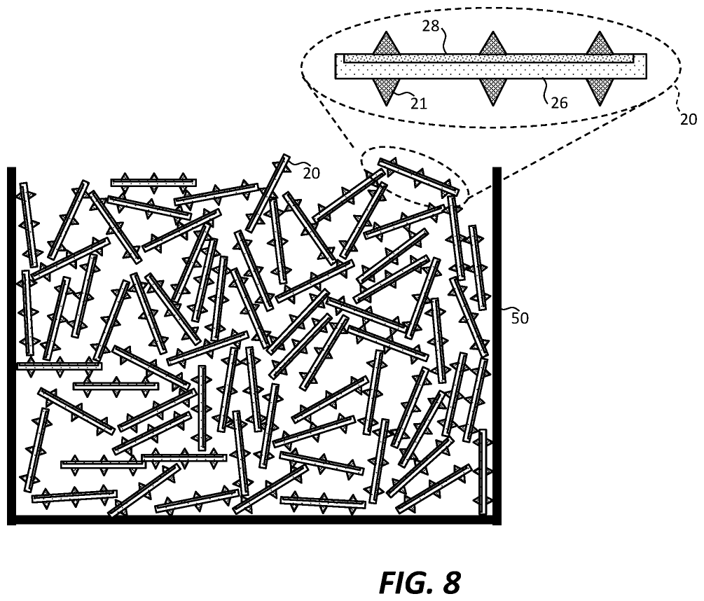

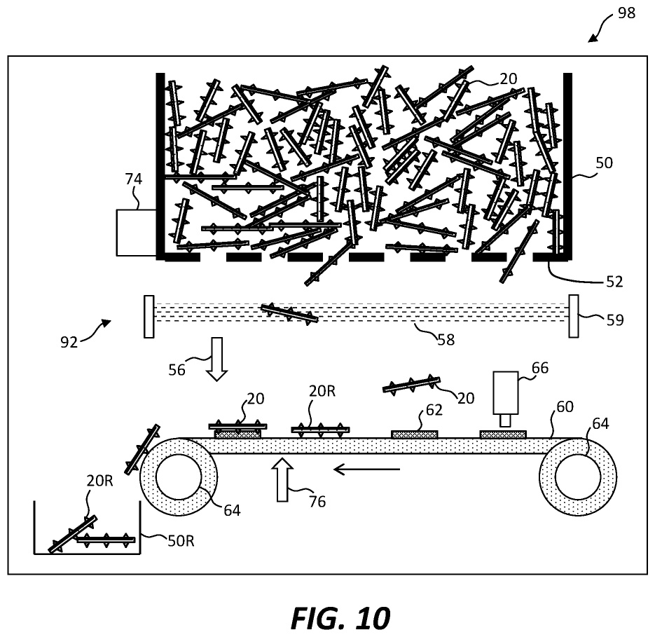

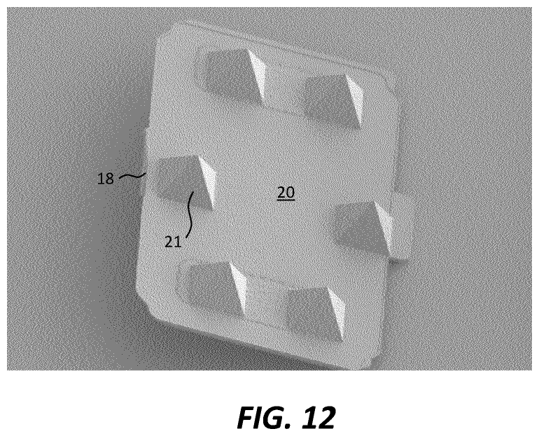

In embodiments of the present disclosure and as shown in FIG. 8, modules 20 can comprise one or more anti-stiction spikes 21, for example as shown in the micrograph of FIG. 12 (e.g., with a fractured tether 18). Anti-stiction spikes 21 can reduce van der Waal's forces or other close-range forces from adhering modules 20 together into flocculated clumps and enabling the disposition of individual separated modules 20 on a receiving surface 60 (e.g., a receiving substrate 60 or surface 60 of a receiving substrate, shown in FIG. 10 discussed below). (For clarity, FIGS. 8-16 do not show components 30 as part of modules 20 and FIGS. 8-11, 13-16 omit tethers 18, if present.) Modules 20 can have a length, a width, or both, not greater than 2500 μm, preferably not greater than 1500 μm, more preferably not greater than 750 μm, more preferably not greater than 500 μm, or more preferably not greater than 250 μm. Modules 20 can have a thickness not greater than 100 μm, preferably not greater than 50 μm, more preferably not greater than 20 μm, more preferably not greater than 10 μm, more preferably not greater than 5 μm, or more preferably not greater than 2 μm. Modules 20 can have a length or width over the receiving surface 60 that is no less than two, preferably no less than five, more preferably no less than ten, more preferably no less than twenty, more preferably no less than fifty, or more preferably no less than one hundred times the thickness of modules 20. Such small modules 20 are not easily removed from module source wafer 10 and distributed on a receiving surface 60 (shown in FIG. 10) using methods of the prior art. Modules 20 can be light-emitting modules 20.

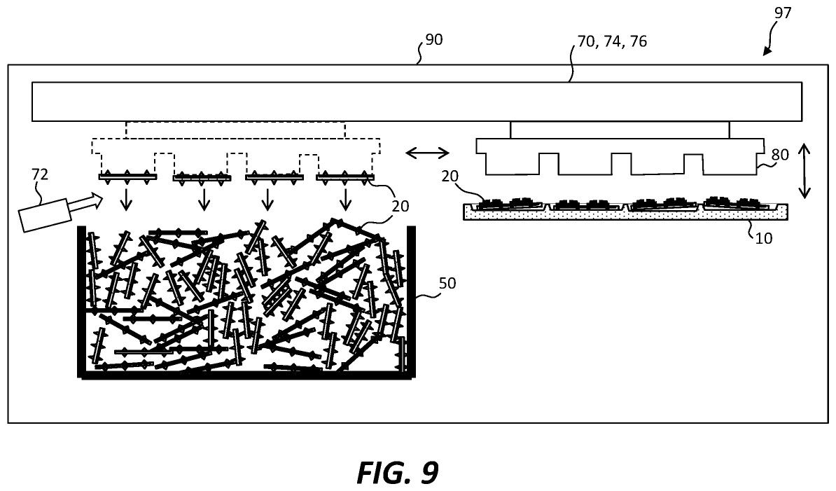

According to embodiments of the present disclosure and as illustrated in FIG. 9, a module collection system 97 comprises a container 50, a module source wafer 10 comprising modules 20 released from module source wafer 10, and a module collection device 90 operable to remove modules 20 from module source wafer 10 in step 120 and dispose modules 20 as a disordered and dry collection into container 50 in step 140, where each module 20 comprises an electronically active unpackaged component 30. Component 30 can be disposed on a component substrate or module substrate 26. Module collection device 90 can comprise a motion platform 70 and a module removal device 72 (that can, for example, incorporate one or more of a piezoelectric vibrator 74, a heater 76, a rinsing device and filter, a stream 54 of liquid and filter, or a stream 54 of gas) disposed in a housing into and from which container 50 and module source wafer 10 can be inserted. Modules 20 detached from module source wafer 10 or stamp 80 can be entrained in a flow 56 of gas, liquid, or an ionized plasma, for example in a direction of gravity 78, to facilitate removal from module source wafer 10 or stamp 80 and collection into a container 50. In some embodiments, module source wafer 10 is disposed top-side up, modules 20 fall first into gap 15 when module source wafer 10 is etched, and then, after module source wafer 10 is inverted, modules 20 fall out of gap 15 into container 50.

Referring to FIG. 10 and again to FIG. 1, according to embodiments of the present disclosure, a receiving surface 60 is provided in step 145 and modules 20 are removed from container 50 in step 160 and disposed on a receiving surface 60 in step 170. (Steps 160 and 170 can be a common step.) Receiving surface 60 is chosen from the group: a surface of a document, a surface of a banknote, a surface of a foil, a surface of a ribbon, and a substrate incorporated into a document or banknote. Receiving surface 60 can be a surface of a paper, polymer, plastic, PET, or PEN substrate. In some embodiments, receiving surface 60 is reflective and can reflect light emitted from module 20. Receiving surface 60 can be a surface of a flexible web (e.g., a polymer substrate such as mylar with or without coatings such as a reflective (e.g., aluminized) layer) and can be provided in a roll on a roller 64 and processed by unwinding the web and then winding the web on a take-up roller 64 in a roll-to-roll manufacturing system. Such rolling and unrolling can also occur for other receiving surfaces 64, such as flexible foils or ribbons. Some methods, therefore, comprise moving receiving surface 60 in a direction (e.g., horizontally) at least partially orthogonal to the direction of the force of gravity 78 (e.g., vertical) while disposing modules 20 on receiving surface 60, so that modules 20 fall from container 50 or sieve 52 (e.g., vertically) onto a moving web that comprises receiving surface 60.

Modules 20 can be randomly disposed on receiving surface 60, for example by sprinkling modules 20 onto receiving surface 60 from a container 50, such as a container 50 that is a sieve 52 with a vibrator 74 that comprises holes of a pre-determined size that allows individual modules 20 to fall from container 50 onto locations on receiving surface 60. As used herein, randomly disposed modules 20 are disposed on locations of receiving surface 60 without individually and controllably disposing each module 20 on a pre-determined location on receiving surface 60. Module 20 locations on receiving surface 60 are not necessarily mathematically randomly located on receiving surface 60. A dry and disordered collection of modules 20 are more readily disposed in pre-determined locations on desirable receiving surfaces than a liquid slurry of modules 20 that can be more difficult to control, which requires drying after deposition, and can damage some receiving surfaces 60.

Modules 20 can be entrained in a flow 56 of gas to assist in disposing modules 20 on receiving surface 60. Some methods of the present disclosure comprise providing an electric or magnetic field 58, for example with plates 59 to orient modules 20 with respect to receiving surface 60. In some embodiments, receiving surface 60 has a patterned surface energy (for example a pattern of hydrophilic or hydrophobic areas on receiving surface 60) that can orient modules 20 with respect to receiving surface 60.

Receiving surface 60 can be coated with adhesive 62 to adhere at least some modules 20 to receiving surface 60, for example coating a liquid adhesive 62 using a slot coater in optional step 150. Optional step 150 can be performed at any time before modules 20 are disposed on receiving surface 60, for example before step 160. Adhesive 62 can be patterned, for example using photolithographic techniques. In some embodiments, adhesive 62 is pattern-wise deposited on receiving surface 60, for example with an inkjet printer 66. Modules 20 that fall onto adhesive 62 on receiving surface 60 in step 170 are then adhered in the pattern of adhesive 62. Modules 20 that do not fall on patterned adhesive 62 are not adhered to receiving surface 60. According to some embodiments of the present disclosure, a heater 76 can heat adhesive 62 to reduce the viscosity of adhesive 62 and orient adhered modules 20 with respect to receiving surface 60 in optional step 180, and then cooling adhesive 62. Reducing the viscosity of adhesive 62 can wick adhesive 62 along receiving surface 60 forcing modules 20 to align a major surface (e.g., length or width) of modules 20 parallel to receiving surface 60 (as shown in FIG. 15). Adhesive 62 (and adhered modules 20) can have a pattern that complements markings on receiving surface 60 or that has a useful and distinctive pattern. Adhesive 62 with adhered modules 20 can be cured, for example by radiation (e.g., ultra-violet radiation) or by a thermal treatment in step 190.

Recycled modules 20R that do not fall onto adhesive 62 on receiving surface 60 can fall off or otherwise be removed from receiving surface 60, collected in a recycling container 50R, and subsequently redeposited on receiving surface 60, so that recycled modules 20R are not wasted. In some embodiments, methods comprise vibrating receiving surface 60 (e.g., so that non-adhered modules 20 fall off receiving surface 60), re-orienting receiving surface 60 (e.g., with a take-up roller 64 so that receiving surface 60 becomes at least partially parallel to the direction of gravity 78 and non-adhered modules 20 fall off receiving surface 60, e.g., vertically), rinsing receiving surface 60 (e.g., so that non-adhered modules 20 are rinsed off receiving surface 60), or exposing receiving surface 60 to a stream 54 of gas or liquid (e.g., to remove non-adhered modules 20 from receiving surface 60). Non-adhered modules 20 can be entrained in a flow 56 of gas or liquid while removing non-adhered modules 20 from receiving surface 60. Thus, embodiments of the present disclosure can comprise removing non-adhered modules 20 from receiving surface 60 and adding them back to the collection so that the non-adhered modules 20 become recycled modules 20R. Recycling container 50R can be disposed under or adjacent to receiving surface 60 to collect non-adhered modules 20.

In some embodiments, in a two-step process, modules 20 are disposed on a non-adhesive intermediate substrate, for example a conveyer belt, and then poured onto receiving surface 60.

As shown in FIG. 10, a module deposition system 98 comprises a container 50 containing a disordered and dry collection of modules 20, a module deposition device 92 for removing modules 20 from container 50 and randomly disposing modules 20 on receiving surface 60, wherein each module 20 comprises an electronically active unpackaged component 30. Module deposition system 98 can be disposed or comprise a housing into and from which container 50 can be inserted and in which receiving substrate 60 can be made available or disposed.

In embodiments of the present disclosure, module deposition device 92 comprises a sprinkler for randomly disposing modules 20 on receiving surface 60, a vibrating sieve 52 (e.g., a container 50 with holes and a vibrator 74) for randomly disposing modules 20 on receiving surface 60 or is operable to randomly dispose modules 20 on an intermediate substrate and pour modules 20 from the intermediate substrate onto receiving surface 60. Module deposition device 92 can be operable to move receiving surface 60 in a direction at least partially orthogonal (e.g., substantially parallel) to the direction of the force of gravity 78 while disposing modules 20 on receiving surface 60, for example with a web disposed on rollers 64. Module deposition device 92 can be operable to coat a layer of adhesive 62 on receiving surface 60, for example with a slot or curtain coater. Deposition device can be operable to pattern a layer of adhesive 62 on receiving surface 60, for example with an inkjet printer 66. Module deposition device 92 can be operable to remove non-adhered modules 20 from receiving surface 60 and add them back to the collection, for example by vibrating receiving surface 60, re-orienting receiving surface 60, rinsing receiving surface 60, or exposing receiving surface 60 to a stream 54 of gas or liquid to remove non-adhered modules 20 from receiving surface 60. Module deposition device 92 can be operable to entrain modules 20 in a flow 56 of gas or flow 56 of liquid when removing non-adhered modules 20 from receiving surface 60. If a liquid is used and forms a slurry with the non-adhered modules 20, the slurry can be filtered to remove modules 20 from the liquid.

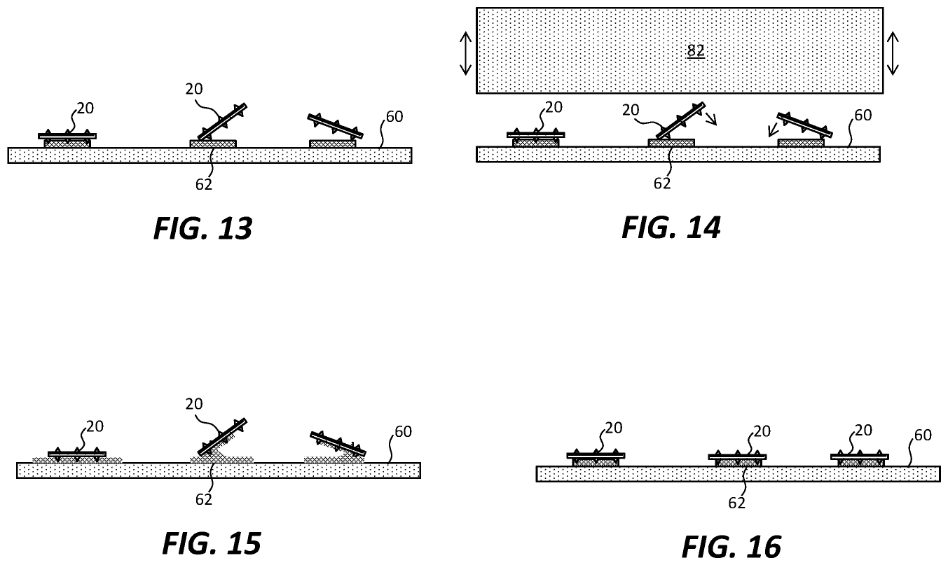

As shown in FIG. 13, modules 20 randomly disposed on patterned adhesive 62 can have a variety of orientations with respect to receiving surface 60 when embedded in adhesive 62, for example substantially parallel to receiving surface 60 or at an orthogonal or non-parallel angle to receiving surface 60. Modules 20 can have a length and width defining a module side much greater than a thickness and it can be desirable to orient modules 20 with the module side substantially parallel to receiving surface 60 (ignoring anti-stiction spikes 21), for example to emit light in a direction orthogonal to receiving surface 60. In some embodiments of the present disclosure, the orientation of modules 20 with respect to receiving surface 60 does not substantially compromise the function of modules 20. In some embodiments, the orientation of modules 20 with respect to receiving surface 60 does compromise the function of modules 20 (e.g., modules 20 might emit light in an undesired direction) and therefore one or more additional module 20 orientation process steps (step 180 in FIG. 1) can be performed after modules 20 are disposed on patterned adhesive 62 on receiving surface 60.

As shown in FIG. 10, module deposition device 92 can comprise a heater 76 for heating adhesive 62 to reduce the viscosity of adhesive 62 so that adhesive 62 reflows to coat modules 20 with adhesive 62 and use surface energy to orient modules 20 with respect to receiving surface 60. Module deposition device 92 can be operable to apply an electric or magnetic field 58 to orient modules 20 with respect to receiving surface 60, for example with plates 59. Since active electronic components 30 can be at least partially responsive to magnetic or electrical fields (e.g., comprising magnetic and/or polarizable materials), a field 58 can produce a force on modules 20 that can align modules 20 within the field 58 and orient modules 20 with a major surface parallel to receiving surface 60. A major surface is a length or width of module 20 and is much greater than a thickness of module 20.

As shown in FIG. 14, an orientation stamp 82 is pressed on the uncured adhesive 62 to mechanically orient module sides of modules 20 substantially parallel to receiving surface 60 in uncured adhesive 62. Orientation stamp 82 can be a printing stamp 80 or a stamp with a stiffer or harder surface, such as a cured polymer, metal, ceramic, or glass surface.

As shown in FIG. 15, surface tension forces can orient modules 20 with respect to receiving surface 60 by reducing the viscosity of adhesive 62 to wick adhesive 62 over surfaces of module 20 and receiving surface 60 and using surface energy to re-orient modules 20.

FIG. 16 illustrates modules 20 re-oriented on receiving surface 60. Adhesive 62 can then be cured in step 190 to fix modules 20 in a desired orientation with respect to receiving surface 60.

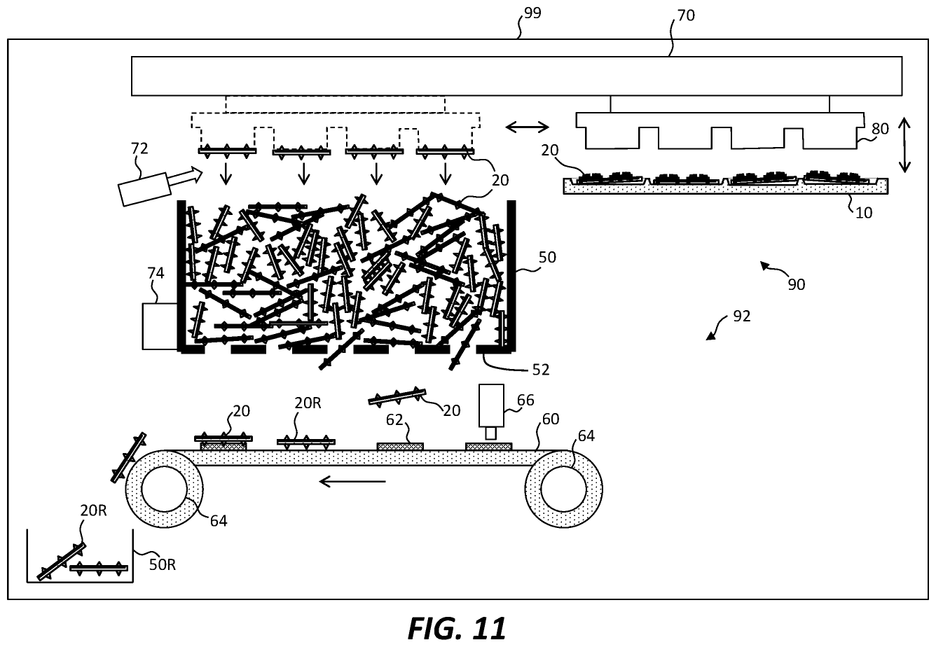

According to some embodiments of the present disclosure and as illustrated in FIG. 11 (combining FIGS. 9 and 10), a module collection and deposition system 99 comprises a container 50, a module source wafer 10 comprising modules 20 released from module source wafer 10, a module collection device 90 operable to remove modules 20 from module source wafer 10 and dispose modules 20 as a disordered and dry collection into container 50, and a module deposition device 92 for removing modules 20 from container 50 and randomly disposing modules 20 on a receiving surface 60. Module collection and deposition system 99 can comprise a housing into and from which module source wafer 10 can be inserted and in which receiving substrate 60 can be made available or disposed. In some embodiments, module collection and deposition system 99 incorporates or comprises both module deposition system 98 and module collection system 97 in a common housing or interconnected and commonly controlled system. Each module 20 comprises an electronically active unpackaged component 30 or multiple electronically active unpackaged components 30 that can each comprise a module substrate 26 or component substrate. Module collection and deposition system 99 can comprise module collection system 97 and module deposition system 98 in combination. Elements of module collection system 97 and module deposition system 98 can be shared in module collection and deposition system 99.

Module collection and deposition system 99 can enable methods of the present disclosure, for example and according to illustrative embodiments providing a module source wafer 10 having modules 20 in step 100, removing modules 20 from module source wafer 10 in step 120, disposing modules 20 as a disordered and dry collection into a container 50 in step 140, removing modules 20 from container 50 in step 160, and disposing modules 20 on a receiving surface 60 in step 170. Each module 20 comprises one or more electronically active unpackaged components 30. Steps 120 and 140 can be done as a common step with common actions. Similarly, steps 160 and 170 can be done as a common step with common actions.

According to embodiments of the present disclosure, modules 20 are substantially rigid and receiving surface 60 is a receiving surface 60 of a receiving substrate that is substantially flexible. A substantially rigid module 20 is a module 20 that is expected to remain rigid and unflexed in common use and a substantially flexible receiving substrate is expected to flex in common use. In some embodiments, module 20 is relatively rigid (e.g., more rigid) compared to a relatively flexible receiving surface 60 (e.g., less rigid and more flexible). In some such embodiments, module 20 (and module substrate 26) is expected to flex in common use, but less than receiving surface 60. In some embodiments, components 30 are more rigid than modules 20 (or module substrate 26) and modules 20 (or module substrates 26) are more rigid than receiving surface 60.

Components 30 can be prepared on a native source substrate and printed (e.g., micro-transfer printed) to module substrate 26 (e.g., comprising plastic, metal, glass, ceramic, sapphire, transparent materials, opaque materials, rigid materials, or flexible materials), thereby obviating the need to manufacture components 30 on module substrate 26. Components 30 can be individually or in combination selected from the group: small integrated circuits, micro-devices, chiplets, unpackaged dies released from a native source substrate, micro-transfer printed components. The components 30 can comprise broken (e.g., fractured) or separated tethers 18. Thus, a micro-transfer-printed component 30 can be a component 30 that is formed on a native component source wafer, released from the component source wafer so that component 30 is attached to the component source wafer by only a tether, contacted by a stamp, removed from the component source wafer by the stamp so that the tether fractures or is separated from the component source wafer, transferred by the stamp to module substrate 26, and contacted and adhered to module substrate 26 while the stamp is removed.

Components 30 can be micro-transfer-printable components 30 and can have at least one of a width and/or length and/or height from 2 μm to 1000 μm, preferably from 2 μm to 500 μm, more preferably from 2 μm to 250 μm, more preferably from 5 μm to 100 μm, or more preferably from 500 μm to 1000 μm.

In some embodiments, components 30 can have a doped or undoped semiconductor substrate thickness of 2 to 50 μm, preferably from 2 to 30 μm, more preferably from 5 to 20 μm, more preferably from 10 to 20 μm, or more preferably from 20 to 50 μm. Components 30 can be integrated circuits with a length greater than width, for example having an aspect ratio greater than or equal to 2, preferably at least 4, more preferably at least 8, more preferably at least 10, more preferably at least 20, or more preferably at least 50, and component electrical contacts 32 that are adjacent to the ends of transfer-printable components 30 along the length of the transfer-printable components 30.

A micro-transfer printable component 30 or module 20 can be or include an active electrical component 30 or module 20, for example including one or more active elements such as electronic transistors or diodes. Components 30 or modules 20 can be or include electronic processors, controllers, drivers, light-emitters, sensors, light-control devices, electrical power generators, electrical power convertors, or light-management devices. Components 30 or modules 20 can be or include integrated circuits, for example CMOS integrated circuits made on or in a silicon semiconductor source substrate (e.g., a wafer), light-emitting diodes (LEDs) or lasers, for example made on or in a compound semiconductor source substrate (a wafer), or silicon photodiodes.

Modules 20 or components 30 can comprise one or more passive elements such as resistors, capacitors, or conductors such as electrical jumpers. In some embodiments, Module 20 includes one or more of both active and passive elements or circuits. In some embodiments, module 20 is a compound element including a plurality of active elements, a plurality of passive elements, or both active and passive element(s), such as multiple semiconductor devices with separate substrates, for example each with one or more active elements or passive elements, or both. In certain embodiments, the plurality of elements is disposed and interconnected on non-native module substrate 26 separate from the substrates of any components 30. Module 20 can be transfer printed itself after the components 30 have been assembled and interconnected thereon (e.g., disposed into container 50).

Printable component 30 or module 20 structures can be made in a semiconductor source substrate (e.g., a native silicon or GaN wafer) having a process side and a back side used to handle and transport the wafer. Transfer-printable components 30 or modules 20 can be formed using lithographic processes in an active layer on or in the process side of a source component substrate (e.g., a native substrate). An empty release layer space or gap 15 (etched sacrificial portion 14) is formed beneath transfer-printable component 30 or module 20 with tethers 18 (e.g., module tethers 18) connecting transfer-printable component 30 or module 20 to anchors 16 on the source substrate in such a way that pressure applied against transfer-printable components 30 or module 20 breaks (e.g., fractures) tethers 18 (e.g., module tethers 18) to release transfer-printable components 30 or module 20 from the source substrate (e.g., with a stamp 80 such as a visco-elastic PDMS stamp 80). Methods of forming such structures are described, for example, in U.S. Pat. No. 8,889,485. Lithographic processes for forming transfer-printable component 30 or module 20 in a source substrate, for example transistors, wires, and capacitors, are found in the integrated circuit art.

According to some embodiments of the present disclosure, a component source substrate can be a component source wafer, for example a semiconductor wafer such as a crystalline silicon or compound semiconductor wafer, or a glass, sapphire, quartz, or polymer substrate or any substrate material capable of supporting transfer-printable components 30. Micro-structured stamps 80 (e.g., elastomeric stamps, visco-elastic stamps, PDMS stamps, vacuum stamps, electrostatic stamps, or hybrid elastomeric/electrostatic stamps) can be used to pick up components 30 from a native source substrate, transport components 30 to module substrate 26, and print components 30 onto module substrate 26. In some embodiments, surface adhesion forces are used to control the selection and printing of components 30 onto module substrate 26. In some embodiments, other forces adhere components 30 to a stamp 80, for example electro-static, vacuum, or magnetic forces. This process may be performed massively in parallel. Stamps 80 can be designed to transfer a single component 30 or module 20 or hundreds to thousands of discrete components 30 or modules 20 in a single pick-up and print operation. For a discussion of micro-transfer printing generally, see U.S. Pat. Nos. 7,622,367 and 8,506,867, each of which is hereby incorporated by reference in its entirety. Stamps 80 can be constructed by photolithographically defining a master mold against which liquid material (e.g., PDMS) is cast and solidified to form a stamp 80. Stamp 80 is then removed from the master mold. Stamp 80 can have a rigid back to which a stamp body is adhered, for example a transparent rigid back comprising glass, on an opposite side of the stamp body from which stamp posts extend.

According to various embodiments of the present invention, a native source substrate (native source wafer) can be provided with the transfer-printable components 30 or modules 20, sacrificial portions 14, and tethers 18 already formed, or they can be constructed as part of the process of the present disclosure.

Native source substrates and transfer-printable components 30, stamps 80, modules 20, and receiving substrates (e.g., providing receiving surface 60) can be made separately and at different times or in different temporal orders or locations and provided in various process states.

As is understood by those skilled in the art, the terms “over” and “under” are relative terms and can be interchanged in reference to different orientations of the layers, elements, and substrates included in the present invention. For example, a first layer on a second layer, in some implementations means a first layer directly on and in contact with a second layer. In other implementations a first layer on a second layer includes a first layer and a second layer with another layer therebetween.

Having described certain implementations of embodiments, it will now become apparent to one of skill in the art that other implementations incorporating the concepts of the disclosure may be used. Therefore, the disclosure should not be limited to certain implementations, but rather should be limited only by the spirit and scope of the following claims.

Throughout the description, where apparatus and systems are described as having, including, or comprising specific components, or where processes and methods are described as having, including, or comprising specific steps, it is contemplated that, additionally, there are apparatus, and systems of the disclosed technology that consist essentially of, or consist of, the recited components, and that there are processes and methods according to the disclosed technology that consist essentially of, or consist of, the recited processing steps.

It should be understood that the order of steps or order for performing certain action is immaterial so long as the disclosed technology remains operable. Moreover, two or more steps or actions in some circumstances can be conducted simultaneously. The invention has been described in detail with particular reference to certain embodiments thereof, but it will be understood that variations and modifications can be effected within the spirit and scope of the invention.

### PARTS LIST

10 module source wafer/wafer
11 bulk layer
12 sacrificial layer
14 sacrificial portion
15 gap
16 anchor
18 tether
19 protective temporary tether
20 module
20R recycled module
21 anti-stiction spikes
22 module electrical contact
24 module electrode
26 module substrate
27 epitaxial layer
28 module circuit
30 component/micro-device
32 component electrical contact
40 dielectric/dielectric layer
50 container
50R recycling container
52 sieve
54 stream
56 flow
58 field
59 plate
60 receiving surface/receiving substrate
62 adhesive
64 roller
66 inkstream printer
70 motion platform
72 module removal device
74 vibrator
76 heater
78 direction of gravity
80 stamp
82 orientation stamp
90 module collection device
92 module deposition device
97 module collection system
98 module deposition system
99 module collection and deposition system
100 provide wafer with modules step
110 etch sacrificial portions step
120 remove modules from wafer step
130 provide container step
140 dispose modules in container step
145 provide receiving surface step
150 optional coat adhesive on surface step
160 remove modules from container step
170 dispose modules on receiving surface step
180 orient modules on surface step
190 cure adhesive

What is claimed:

1. A method of collecting and disposing modules, comprising:
providing a module source wafer comprising modules;
removing the modules from the module source wafer;
disposing the modules as a disordered and dry collection into a container;
removing the modules from the container; and
disposing the modules on a receiving surface,
wherein each module comprises an electronically active unpackaged component.

2. The method of claim 1, wherein the module source wafer further comprises a sacrificial layer comprising laterally spaced-apart sacrificial portions, wherein each of the modules is disposed entirely over one of the sacrificial portions and the method comprises dry or wet etching the sacrificial portions to release the modules from the module source wafer.

3. The method of claim 2, wherein, after releasing the modules from the module source wafer, each of the modules is physically attached to the module source wafer by a tether.

4. The method of claim 2, wherein after releasing the modules from the module source wafer, the modules are physically detached from the module source wafer.

5. The method of any one of the preceding claims, wherein removing the modules from the module source wafer comprises disposing the module source wafer with the modules near the container and etching the module source wafer with a dry etch so that the modules fall toward the bottom of the container.

6. The method of any one of the preceding claims, wherein removing the modules from the module source wafer comprises vibrating the module source wafer or modules.

7. The method of claim 6, wherein vibrating the module source wafer comprises mechanically or sonically vibrating the modules, particularly by mechanically or sonically vibrating the module source wafer.

8. The method of any one of the preceding claims, wherein removing the modules from the module source wafer comprises directing a stream of gas onto the module source wafer such that the modules are released from the module source wafer.

9. The method of any one of the preceding claims, wherein removing the modules comprises:
rinsing the module source wafer with a liquid, preferably by directing a stream of liquid onto the module source wafer, such that the modules are removed from the module source wafer and a slurry of modules and liquid is formed;
filtering the slurry with a filter to separate the liquid from the modules; and
disposing the modules in the container.

10. The method of any one of the preceding claims, wherein removing the modules from the module source wafer comprises thinning the module source wafer and dicing the modules.

11. The method of any one of the preceding claims, wherein removing the modules comprises contacting the modules with a stamp to adhere the modules to the stamp, removing the stamp and the modules from the module source wafer, detaching the modules from the stamp, and collecting the modules in the container, particularly wherein detaching the modules causes the modules to fall into the container.

12. The method of claim 11, wherein detaching the modules from the stamp comprises any one or combination of (i) heating the stamp or the modules; (ii) exposing the stamp or modules to radiation, (iii) vibrating the stamp, (iv) exposing the stamp to vibration, (v) rinsing the stamp, (vi) directing a stream of liquid onto the modules, and (vii) directing a stream of gas onto the modules.

13. The method of any one of the preceding claims, wherein the receiving surface is chosen from the group: a surface of a document, a surface of a banknote, a surface of a foil, a surface of a ribbon, and a substrate incorporated into a document or banknote.

14. The method of any one of the preceding claims, wherein the receiving surface is a substrate and the method comprises incorporating the substrate into a document or banknote.

15. The method of claim 14, wherein the substrate is a foil or a ribbon.

16. The method of any one of the preceding claims, wherein removing the modules from the module source wafer comprises turning over the module source wafer such that the modules fall toward the bottom of the container.

17. The method of any one of the preceding claims, comprising entraining the modules in a flow of gas or flow of liquid while removing the modules from the module source wafer.

18. The method of any one of the preceding claims, wherein each of the modules comprises one or more anti-stiction spikes.

19. The method of any one of the preceding claims, wherein the modules each have a length and a width independently not greater than 2500 μm, preferably not greater than 1500 μm, more preferably not greater than 750 μm, more preferably not greater than 500 μm, or more preferably not greater than 250 μm.

20. The method of any one of the preceding claims, wherein the modules are light-emitting modules.

21. The method of any one of the preceding claims, wherein the modules each have at least one of a length and a width over the receiving surface that is no less than two, preferably no less than five, more preferably no less than ten, more preferably no less than twenty, more preferably no less than fifty, or more preferably no less than one hundred times the thickness of the modules.

22. The method of any one of the preceding claims, wherein each of the modules comprises a broken, particularly fractured, or separated tether.

23. The method of any one of the preceding claims, wherein disposing the modules on a receiving surface comprises randomly sprinkling the modules onto the receiving surface, disposing the modules in a vibrating sieve over the receiving surface, or randomly disposing the modules on an intermediate surface and pouring the modules from the intermediate surface onto the receiving surface.

24. The method of any one of the preceding claims, comprising moving the receiving surface in a direction at least partially orthogonal to the force of gravity while disposing the modules on the receiving surface.

25. The method of any one of the preceding claims, comprising coating a layer of adhesive on the receiving surface that adheres at least some of the modules to the receiving surface.

26. The method of claim 25, comprising coating a patterned layer of adhesive that adheres only some of the modules to the receiving surface in the pattern.

27. The method of claim 25 or claim 26, comprising heating the adhesive to reduce the viscosity of the adhesive and orient the modules with respect to the receiving surface and then cooling the adhesive, curing the adhesive using electromagnetic radiation, or curing the adhesive using a thermal treatment.

28. The method of any one of claims 25 to 27, comprising removing one or more non-adhered modules from the receiving surface and adding them back to the collection.

29. The method of claim 28, comprising vibrating the receiving surface, re-orienting the receiving surface, rinsing the receiving surface, or exposing the receiving surface to a stream of gas or liquid to remove the one or more non-adhered modules from the receiving surface.

30. The method of claim 29, comprising entraining the modules in a flow of gas or flow of liquid while removing the one or more non-adhered modules from the receiving surface.

31. The method of claim 1, comprising orienting the modules with respect to the receiving surface, preferably as or after the modules are disposed on the receiving surface, particularly by providing an electric field and/or a magnetic field and/or a pattern of surface energy on the receiving surface.

32. The method of claim 1, wherein the receiving surface is reflective.

33. A method of collecting modules, comprising:
providing a module source wafer comprising modules;
removing the modules from the module source wafer; and
disposing the modules as a disordered and dry collection into a container, wherein each of the modules comprises an electronically active unpackaged component.

34. The method of claim 33, wherein the module source wafer further comprises a sacrificial layer comprising laterally spaced-apart sacrificial portions, wherein each of the modules is disposed entirely over one of the sacrificial portions and the method comprises dry or wet etching the sacrificial portions to release the modules from the module source wafer.

35. The method of claim 34, wherein after releasing the modules from the module source wafer, each of the modules is physically attached to the module source wafer by a tether.

36. The method of claim 34, wherein after releasing the modules from the module source wafer, the modules are physically detached from the module source wafer.

37. The method of any one of claims 33 to 36, wherein removing the modules from the module source wafer comprises disposing the module source wafer with the modules near the container and etching the module source wafer with a dry etch so that the modules fall toward the bottom of the container.

38. The method of any one of claims 33 to 37, wherein removing the modules from the module source wafer comprises vibrating the module source wafer or modules.

39. The method of claim 38, wherein vibrating the module source wafer comprises mechanically or sonically vibrating the modules, preferably by mechanically or sonically vibrating the module source wafer.

40. The method of any one of claims 33 to 39, wherein removing the modules from the module source wafer comprises directing a stream of gas onto the module source wafer such that the modules are released from the module source wafer.

41. The method of any one of claims 33 to 40, wherein removing the modules comprises:
rinsing the module source wafer with a liquid, preferably by directing a stream of liquid onto the module source wafer such that the modules are removed from the module source wafer and a slurry of modules and liquid is formed;
filtering the slurry with a filter to separate the liquid from the modules; and
disposing the modules in the container.

42. The method of claim 33, wherein removing the modules from the module source wafer comprises thinning the module source wafer and dicing the modules.

43. The method of any one of claims 33 to 41, wherein removing the modules comprises contacting the modules with a stamp to adhere the modules to the stamp, removing the stamp and the modules from the module source wafer, detaching the modules from the stamp, and collecting the modules in the container, particularly wherein detaching the modules causes the modules to fall into the container.

44. The method of claim 43, wherein detaching the modules from the stamp comprises any one or combination of (i) heating the stamp or the modules; (ii) exposing the stamp or modules to radiation, (iii) vibrating the stamp, (iv) exposing the stamp to vibration, (v) rinsing the stamp, (vi) directing a stream of liquid onto the modules, and (vii) directing a stream of gas onto the modules.

45. The method of any one of claims 33 to 44, wherein removing the modules from the module source wafer comprises turning over the module source wafer such that the modules fall toward the bottom of the container.

46. The method of any one of claims 33 to 45, comprising entraining the modules in a flow of gas or flow of liquid while removing the modules from the module source wafer.

47. The method of any one of claims 33 to 46, wherein each of the modules comprises one or more anti-stiction spikes.

48. The method of any one of claims 33 to 47, wherein the modules each have a length and a width independently not greater than 2500 μm, preferably not greater than 1500 μm, more preferably not greater than 750 μm, more preferably not greater than 500 μm, or more preferably not greater than 250 μm.

49. The method of claim 33, wherein the modules are light-emitting modules.

50. The method of claim 33, wherein the modules each have at least one of a length and a width over the receiving surface that is no less than two, preferably no less than five, more preferably no less than ten, more preferably no less than twenty, more preferably no less than fifty, or more preferably no less than one hundred times the thickness of the modules.

51. The method of claim 33, wherein each of the modules comprises a broken, particularly fractured, or separated tether.

52. A method of disposing a collection of modules on a receiving surface, comprising:
providing a disordered and dry collection of modules in a container;
removing the modules from the container; and
disposing the modules on the receiving surface,
wherein each of the modules comprises an electronically active unpackaged component.

53. The method of claim 52, wherein the receiving surface is chosen from the group:
a surface of a document, a surface of a banknote, a surface of a foil, or a surface of a ribbon, and a substrate incorporated into a document or banknote.

54. The method of claim 53, wherein the receiving surface is a substrate and the method comprising incorporating the substrate into a document or banknote.

55. The method of claim 54, wherein the substrate is a foil or a ribbon.

56. The method of any one of claims 52 to 55, wherein each of the modules comprises one or more anti-stiction spikes.

57. The method of any one of claims 52 to 56, wherein the modules each have a length and a width independently not greater than 2500 μm, preferably not greater than 1500 μm, more preferably not greater than 750 μm, more preferably not greater than 500 μm, or more preferably not greater than 250 μm.

58. The method of any one of claims 52 to 57, wherein the modules are light-emitting modules.

59. The method of any one of claims 52 to 58, wherein the modules each have at least one of a length and a width over the receiving surface that is no less than two, preferably no less than five, more preferably no less than ten, more preferably no less than twenty, more preferably no less than fifty, or more preferably no less than one hundred times the thickness of the modules.

60. The method of any one of claims 52 to 59, wherein each of the modules comprises a broken, particularly fractured, or separated tether.

61. The method of any one of claims 52 to 60, wherein removing the modules from the container and disposing the modules on a receiving surface comprises randomly sprinkling the modules onto the receiving surface, disposing the modules in a vibrating sieve over the receiving surface, or randomly disposing the modules on an intermediate surface and pouring the modules from the intermediate surface onto the receiving surface.

62. The method of any one of claims 52 to 61, comprising moving the receiving surface in a direction at least partially orthogonal to the force of gravity while disposing the modules on the receiving surface.

63. The method of any one of claims 52 to 62, comprising coating a layer of adhesive on the receiving surface that adheres at least some of the modules to the receiving surface.

64. The method of claim 63, comprising coating a patterned layer of adhesive that adheres only some of the modules to the receiving surface in the pattern.

65. The method of claim 63 or claim 64, comprising heating the adhesive to reduce the viscosity of the adhesive and orient the at least some of the modules with respect to the receiving surface, and then cooling the adhesive, curing the adhesive using electromagnetic radiation, or curing the adhesive using a thermal treatment.

66. The method of any one of claims 52 to 65, comprising removing one or more non-adhered modules from the receiving surface and adding them back to the collection.

67. The method of claim 66, comprising vibrating the receiving surface, re-orienting the receiving surface, rinsing the receiving surface, or exposing the receiving surface to a stream of gas or liquid to remove the one or more non-adhered modules from the receiving surface.

68. The method of claim 67, comprising entraining the modules in a flow of gas or flow of liquid while removing the one or more non-adhered modules from the receiving surface.

69. The method of any one of claims 52 to 68, comprising providing an electric field, a magnetic field, or a pattern of surface energy on the receiving surface to orient the modules with respect to the receiving surface.

70. The method of any one of claims 52 to 69, wherein the receiving surface is reflective.

71. A module collection and deposition system, comprising:
a container;
a module collection device operable to remove modules from a module source wafer and dispose the modules as a disordered and dry collection into the container; and
a module deposition device for removing the modules from the container and randomly disposing the modules on a receiving surface.

72. The module collection and deposition system of claim 71, wherein the collection device comprises a module removal device that is operable to remove the modules from the module source wafer by directing a stream of gas onto the module source wafer to remove the modules from the module source wafer and dispose the removed modules in the container.

73. The module collection and deposition system of claim 71 or claim 72, wherein the collection device comprising a module removal device and a filter and the module removal device is operable to remove the modules from the module source wafer by rinsing the module source wafer and modules with a liquid, preferably by directing a stream of liquid onto the module source wafer and modules to remove the modules from the module source wafer, and form a slurry of modules and liquid, causing (i) the slurry to be filtered with the filter to separate the liquid from the modules and (ii) the modules to be disposed in the container after being filtered.

74. The module collection and deposition system of any one of claims 71 to 73, wherein the collection device is operable to remove the modules from the module source wafer by disposing the module source wafer in or over the container with a top side of the module source wafer on a side of the module source wafer opposite a bottom of the container and turning over the wafer so that the modules fall toward the bottom of the container.

75. The module collection and deposition system of any one of claims 71 to 74, wherein the collection device comprises a stamp and is operable to remove the modules from the module source wafer by contacting the modules with the stamp to adhere the modules to the stamp, removing the stamp and modules from the module source wafer, detaching the modules from the stamp, and disposing the detached modules in the container, particularly wherein detaching the modules causes the modules to fall into the container.

76. The module collection and deposition system of claim 75, wherein the collection device is operable to (i) heat the stamp or the modules when on the stamp; (ii) expose the stamp or the modules when on the stamp to radiation, (iii) vibrate the stamp or expose the stamp to vibration, (iv) rinse the stamp, (v) direct a stream of liquid onto the modules when on the stamp, or (vi) direct a stream of gas onto the modules when on the stamp.

77. The module collection and deposition system of any one of claims 71 to 76, wherein the collection device comprises a module removal device comprising a vibrator that is disposed to vibrate the module source wafer to remove the modules from the module source wafer.

78. The module collection and deposition system of claim 77, wherein the collection device is operable to vibrate the module source wafer mechanically or sonically.

79. The module collection and deposition system of any one of claims 71 to 78, wherein the collection device comprises a gas or liquid source that is operable to entrain the modules in a flow of gas or flow of liquid, respectively, while removing the modules from the module source wafer.

80. The module collection and deposition system of any one of claims 71 to 79, wherein each of the modules comprises one or more anti-stiction spikes.

81. The module collection and deposition system of any one of claims 71 to 80, wherein the modules have a length and a width independently not greater than 2500 μm, preferably not greater than 1500 μm, more preferably not greater than 750 μm, more preferably not greater than 500 μm, or more preferably not greater than 250 μm.

82. The module collection and deposition system of any one of claims 71 to 81, comprising the modules.

83. The module collection and deposition system of any one of claims 71 to 82, wherein the modules are light-emitting modules.

84. The module collection and deposition system of any one of claims 71 to 83, wherein the modules have a length or width, or both, over the receiving surface that is no less than two (e.g., no less than five, ten, twenty, fifty, or one hundred times) a thickness of the modules when disposed on the receiving surface.

85. The module collection and deposition system of any one of claims 71 to 84, wherein each of the modules comprises a fractured or separated tether.

86. The module collection and deposition system of any one of claims 71 to 85, wherein the deposition device comprises a sprinkler for randomly disposing the modules on the receiving surface, a vibrating sieve for randomly disposing the modules on the receiving surface, or is operable to randomly dispose the modules on an intermediate substrate and pour the modules from the intermediate substrate onto the receiving substrate.

87. The module collection and deposition system of any one of claims 71 to 86, wherein the deposition device is operable to move the receiving surface in a direction at least partially orthogonal to the force of gravity while disposing the modules on the receiving surface.

88. The module collection and deposition system of any one of claims 71 to 87, wherein the deposition device comprises an adhesive source, preferably an inkjet printer or slot coater, that is operable to coat a layer of adhesive on the receiving surface.

89. The module collection and deposition system of claim 88, wherein the adhesive source is operable to pattern the layer of adhesive on the receiving surface.

90. The module collection and deposition system of any one of claims 71 to 89, wherein the deposition device comprises one or more rollers operable to move the receiving surface relative to the container to deposit the modules over the receiving surface, preferably wherein the receiving surface is rolled onto and/or off of one(s) of the one or more rollers.

91. The module collection and deposition system of any one of claims 71 to 90, comprising a recycling container, wherein the deposition device is operable to remove non-adhered modules from the receiving surface, collect them in the recycling container, and add them back to the collection from the recycling container.

92. The module collection and deposition system of claim 91, wherein the recycling container is disposed adjacent to one or more rollers such that non-adhered modules are removed, particularly such that modules that are not adhered to the preferably patterned adhesive are removed and collected in the recycling container by falling into the recycling container.

93. The module collection and deposition system of any one of claims 71 to 92, wherein the deposition device is operable to vibrate the receiving surface, re-orient the receiving surface, rinse the receiving surface, or expose the receiving surface to a stream of gas or liquid to remove non-adhered modules from the receiving surface.

94. The module collection and deposition system of any one of claims 71 to 93, wherein the deposition device comprises a gas or liquid source that is operable to entrain the modules in a flow of gas or flow of liquid, respectively, when removing the non-adhered modules from the receiving surface.

95. The module collection and deposition system of any one of claims 71 to 94, comprising a heater for heating adhesive disposed on the receiving surface to reduce the viscosity of the adhesive and orient the modules with respect to the receiving surface when the modules are disposed on the adhesive.

96. The module collection and deposition system of any one of claims 71 to 95, wherein the deposition device comprises a field source (e.g., plates) that is operable to apply an electric field or a magnetic field to orient the modules with respect to the receiving surface or the system comprises the receiving surface that comprises a surface energy pattern to orient the modules with respect to the receiving surface.

97. The module collection and deposition system of any one of claims 71 to 96, comprising the receiving surface, wherein the receiving surface is reflective.

98. The module collection and deposition system of any one of claims 71 to 97, comprising the receiving surface, wherein the receiving surface is a web.

99. The module collection and deposition system of any one of claims 71 to 98, comprising a coater for coating the modules on the receiving surface.

100. The module collection and deposition system of any one of claims 71 to 99, wherein the receiving surface is chosen from the group: a surface of a document, a surface of a banknote, a surface of a foil, a surface of a ribbon, and a substrate incorporated into a document or banknote.

101. The module collection and deposition system of any one of claims 71 to 97, comprising the module source wafer comprising the modules, particularly modules attached to the module source wafer by tethers, wherein the modules are released from the module source wafer.

102. The module collection and deposition system of any of claims 71 to 101, comprising one or more rollers that are operable to move the receiving surface to dispose the modules over the receiving surface.

103. The module collection and deposition system of claim 102, comprising a recycling container disposed adjacent to the one or more rollers for collecting non-adhered modules.

104. A module collection system, comprising:
a container;
a module source wafer comprising modules released from the module source wafer; and
a collection device operable to remove the modules from the module source wafer and dispose the modules as a disordered and dry collection into the container,
wherein each module comprises an electronically active unpackaged component.

105. The module collection system of claim 104, wherein the collection device comprises a module removal device that is operable to remove the modules from the module source wafer by directing a stream of gas onto the module source wafer to remove the modules from the module source wafer and dispose the removed modules in the container.

106. The module collection system of claim 104 or claim 105, wherein the collection device comprises a module removal device and a filter and the module removal device is operable to remove the modules from the module source wafer by rinsing the module source wafer and modules with a liquid, preferably by directing a stream of liquid onto the module source wafer and modules to remove the modules from the module source wafer and form a slurry of modules and liquid, causing (i) the slurry to be filtered with the filter to separate the liquid from the modules and (ii) the modules to be disposed in the container after being filtered.

107. The module collection system of any one of claims 104 to 106, wherein the collection device is operable to remove the modules from the module source wafer by disposing the module source wafer in or over the container with a top side of the module source wafer on a side of the module source wafer opposite a bottom of the container and turning over the wafer so that the modules fall toward the bottom of the container.

108. The module collection system of any one of claims 104 to 107, wherein the collection device comprises a stamp and is operable to remove the modules from the module source wafer by contacting the modules with the stamp to adhere the modules to the stamp, removing the stamp and modules from the module source wafer, detaching the modules from the stamp, and disposing the detached modules in the container, particularly wherein detaching the modules causes the modules to fall into the container.

109. The module collection system of claim 108, wherein the collection device is operable to (i) heat the stamp or the modules when on the stamp; (ii) expose the stamp or modules when on the stamp to radiation; (iii) vibrate the stamp or expose the stamp to vibration; (iv) rinse the stamp; (v) direct a stream of liquid onto the modules when on the stamp; or (vi) direct a stream of gas onto the modules when on the stamp.

110. The module collection system of any one of claims 104 to 109, wherein the collection device comprises a module removal device comprising a vibrator that is operable to vibrate the module source wafer to remove the modules from the module source wafer.

111. The module collection system of claim 110, wherein the collection device is operable to vibrate the module source wafer mechanically or sonically.

112. The module collection system of any one of claims 104 to 111, wherein the collection device comprises a gas or liquid source that is operable to entrain the modules in a flow of gas or flow of liquid, respectively, while removing the modules from the module source wafer.

113. The module collection system of any one of claims 104 to 112, wherein each of the modules comprises one or more anti-stiction spikes.

114. The module collection system of any one of claims 104 to 113, wherein the modules have a length and a width not greater than 2500 μm, preferably not greater than 1500 μm, more preferably not greater than 750 μm, more preferably not greater than 500 μm, or more preferably not greater than 250 μm.

115. The module collection system of any one of claims 104 to 115, wherein the modules are light-emitting modules.

116. The module collection system of any one of claims 104 to 115, wherein the modules have a length or width, or both, that is no less than two, preferably no less than five, more preferably no less than ten, more preferably no less than twenty, more preferably no less than fifty, or more preferably no less than one hundred times a thickness of the modules.

117. The module collection system of any one of claims 104 to 116, wherein each of the modules comprises a broken, particularly fractured, or separated tether.

118. A module deposition system, comprising:
a container containing a disordered and dry collection of modules; and
a deposition device for removing the modules from the container and randomly disposing the modules on a receiving surface,
wherein each of the modules comprises an electronically active unpackaged component.

119. The module deposition system of claim 118, wherein the deposition device comprises a sprinkler for randomly disposing the modules on the receiving surface, a vibrating sieve for randomly disposing the modules on the receiving surface, or is operable to randomly dispose the modules on an intermediate substrate and pour the modules from the intermediate substrate onto the receiving substrate.

120. The module deposition system of claim 118 or claim 119, wherein the deposition device is operable to move the receiving surface in a direction at least partially orthogonal to the force of gravity while disposing the modules on the receiving surface.

121. The module deposition system of claim 120, wherein the deposition device comprises one or more rollers that are operable to move the receiving surface.

122. The module deposition system of any one of claims 118 to 121, wherein the deposition device comprises an adhesive source, preferably an inkjet printer or slot coater, that is operable to coat a layer of adhesive on the receiving surface.

123. The module deposition system of claim 122, wherein the adhesive source is operable to pattern the layer of adhesive on the receiving surface.

124. The module deposition system of claim 123, comprising a recycling container, wherein the deposition device is operable to remove non-adhered modules from the receiving surface, collect them in the recycling container, and add them back to the collection from the recycling container.

125. The module deposition system of claim 124, wherein the recycling container is disposed adjacent to one or more rollers such that non-adhered modules are removed, particularly such that modules that are not adhered to the preferably patterned adhesive are removed and collected in the recycling container by falling into the recycling container.

126. The module deposition system of any one of claims 118 to 125, wherein the deposition device is operable to vibrate the receiving surface, re-orient the receiving surface, rinse the receiving surface, or expose the receiving surface to a stream of gas or liquid to remove non-adhered modules from the receiving surface.

127. The module deposition system of any one of claims 118 to 126, wherein the deposition device comprises a gas or liquid source that is operable to entrain the modules in a flow of gas or flow of liquid, respectively, when removing the non-adhered modules from the receiving surface.

128. The module deposition system of any one of claims 118 to 127, comprising a heater for heating adhesive disposed on the receiving surface to reduce the viscosity of the adhesive and orient the modules with respect to the receiving surface when the modules are disposed on the adhesive.

129. The module deposition system of any one of claims 118 to 128, wherein the deposition device comprises a field source, particularly in the form of plates, that is operable to apply an electric field or a magnetic field to orient the modules with respect to the receiving surface or the system comprises the receiving surface that comprises a surface energy pattern to orient the modules with respect to the receiving surface.

130. The module deposition system of any one of claims 118 to 129, comprising the receiving surface wherein the receiving surface is reflective.

131. The module deposition system of any one of claims 118 to 130, comprising the receiving surface, wherein the receiving surface is a web.

132. The module deposition system of any one of claims 118 to 131, comprising a coater for coating the modules on the receiving surface.

133. The module deposition system of claim 109, wherein the receiving surface is chosen from the group: a surface of a document, a surface of a banknote, a surface of a foil, a surface of a ribbon, a surface of a foil, a surface of a ribbon, and a substrate incorporated into a document or banknote.
